(19) United States
(12) Patent Application Publication
(10) Pub. No.: US 2024/0429142 A1
(43) Pub. Date: Dec. 26, 2024

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Ming-Hung Tseng, Miaoli County (TW); Tzu-Sung Huang, Tainan City (TW); Tsung-Hsien Chiang, Hsinchu (TW); An-Jhih Su, Taoyuan City (TW); Yu-Jin Hu, Taoyuan City (TW); Hua-Wei Tseng, New Taipei City (TW); Cheng-Hsien Hsieh, Kaohsiung City (TW); Wei-Cheng Wu, Hsinchu City (TW); Der-Chyang Yeh, Hsin-Chu (TW)

(73) Assignee: Taiwan Semiconductor Manufacturing Company, Ltd., Hsinchu (TW)

(21) Appl. No.: 18/340,897

(22) Filed: Jun. 26, 2023

(51) Int. Cl. H01L 23/498; H01L 21/60; H01L 23/00

(52) U.S. Cl. CPC H01L 23/49811; H01L 21/60; H01L 24/06; H01L 24/13; H01L 2021/60232; H01L 2224/0401; H01L 2224/0603; H01L 2224/13006; H01L 2224/13026

(57) ABSTRACT

A semiconductor device includes first IC dies disposed side-by-side, a second IC die overlapping and electrically coupled to the first IC dies, and first conductive features. Each first IC die includes first and second die connectors. A first pitch of the first die connectors is less than a second pitch of the second die connectors and is substantially equal to a third pitch of the third die connectors of the second IC die. The first conductive features are interposed between and electrically coupled to the first and third die connectors. Each first conductive feature includes at least a first conductive bump and at least a first conductive joint.

### BACKGROUND

Semiconductor devices and integrated circuits used in a variety of electronic applications are typically manufactured from a wafer. The integrated circuit (IC) dies of the wafer are processed and packaged with other electronic devices at the wafer level, and various technologies have been developed for wafer level packaging. In addition, for multi-die packages, the arrangement of the IC dies and the packaging techniques affect reliability of the packaged products.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 7 illustrate schematic cross-sectional views of intermediate steps during a process for forming a semiconductor device, in accordance with some embodiments.

FIGS. 8-9, 10A, and 11A illustrate schematic cross-sectional views of intermediate steps during a process for forming a further semiconductor device, in accordance with some embodiments.

FIGS. 10B and 11B illustrate schematic cross-sectional views of intermediate steps during a process for forming a further semiconductor device, in accordance with some embodiments.

FIGS. 12A and 12B illustrate schematic cross-sectional views of variations of a semiconductor device, in accordance with some embodiments.

FIGS. 13 through 20 illustrate schematic cross-sectional views of intermediate steps during a process for forming a semiconductor package, in accordance with some embodiments.

FIGS. 21 through 25 illustrate schematic cross-sectional views of intermediate steps during a process for forming a further semiconductor package, in accordance with some embodiments.

FIGS. 26 and 27 illustrate schematic cross-sectional views of intermediate steps during a process for forming a further semiconductor device, in accordance with some embodiments.

FIGS. 28 through 31 illustrate schematic cross-sectional views of intermediate steps during a process for forming a further semiconductor device, in accordance with some embodiments.

FIG. 32 illustrates a schematic cross-sectional view of a further semiconductor device, in accordance with some embodiments.

FIGS. 33 through 37 illustrate schematic cross-sectional views of intermediate steps during a process for forming a semiconductor device, in accordance with some embodiments.

FIG. 38 illustrates a schematic cross-sectional view of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

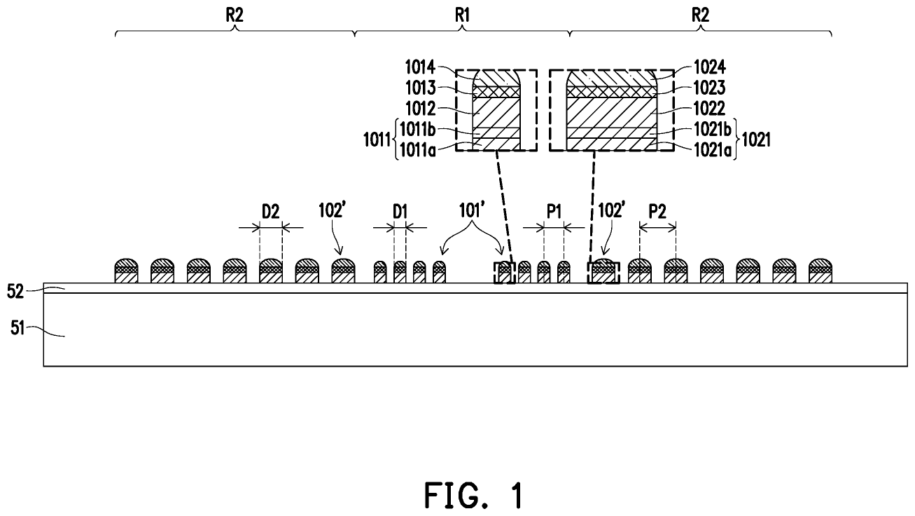

FIGS. 1 through 7 illustrate schematic cross-sectional views of intermediate steps during a process for forming a semiconductor device, in accordance with some embodiments. Although method embodiments are discussed as being performed in a particular order, other embodiments may be performed in any logical order.

Referring to FIG. 1, first conductive bumps 101′ and second conductive bumps 102′ may be formed over a first temporary carrier 51. The first temporary carrier 51 may be made of a suitable material such as silicon, polymer, polymer composite, metal foil, ceramic, glass, glass epoxy, tape, or other suitable material for structural support. In some embodiments, the first temporary carrier 51 is provided with a first release layer 52, and the first conductive bumps 101′ and the second conductive bumps 102′ are formed on the first release layer 52. In some embodiments, the first release layer 52 includes a photosensitive film which is easily detached from the first temporary carrier 51 by shining a light on the first temporary carrier 51 in a subsequent de-bonding process. For example, the first release layer 52 includes a light-to-heat-conversion (LTHC) coating layer. In some embodiments, the first release layer 52 includes a die attach film or any suitable adhesive film.

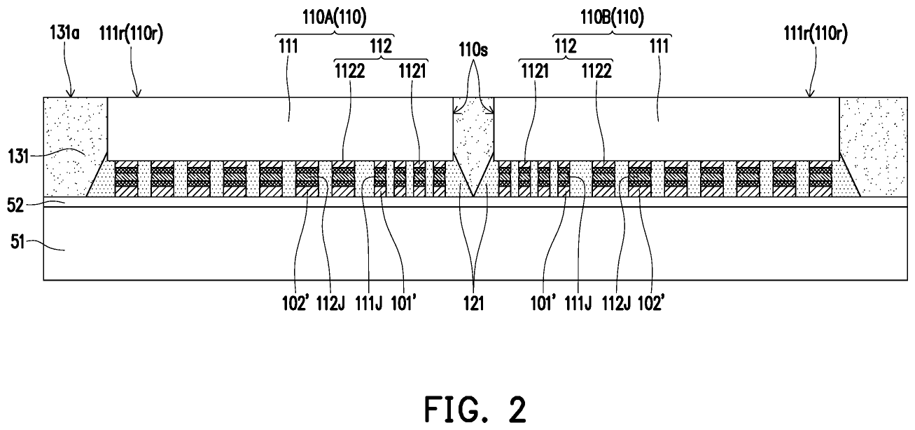

It is appreciated that design for manufacturing (DFM) is an integration of manufacturing data and design procedure for better yield and design efficiency. DFM can be realized at the stage of forming the first and/or second conductive bumps. For example, when curing the insulating material to form the insulating encapsulation in the subsequent process (see FIG. 2), the insulating material deforms, and non-uniform stress may be applied to the respective first integrated circuit (IC) die and cause the first IC dies shift out of their original position after placement. Improper alignment may become more and more problematic as alignment margins decrease due to increasing demand for the dies having fine-pitched die connectors. Various processing deviations introduced from various processing modules may be compensated by tuning layout of the first conductive bumps 101′ and/or second conductive bumps 102′.

The first conductive bumps 101′ may be formed within a first region R1 over the first temporary carrier 50, and the second conductive bumps 102′ may be formed within a second region R2 over the first temporary carrier 50. In a top-down view (not shown), the second region R2 may surround the first region R1. The first conductive bumps 101′ may be formed before (or after) forming the second conductive bumps 102′. In alternative embodiments, the first and second conductive bumps 101′ and 102′ are formed in a same step by using a single photomask. In some embodiments, the formation of the first conductive bumps 101′ and/or second conductive bumps 102′ includes at least the following steps. A seed material layer may be formed over the first temporary carrier 51. For example, the seed material layer is a composite layer including a first material sublayer and a second material sublayer stacked on the first material sublayer, where the first and second material sublayers are formed of different materials. In some embodiments, the first material sublayer is formed of titanium and the second material sublayer is formed of copper. Alternatively, the seed material layer is a single layer which is formed of copper or copper alloys. Next, a photoresist may be formed and patterned on the seed material layer in accordance with a desired metallization pattern. Conductive materials (e.g., copper, nickel, tin, lead, gold, palladium, indium, etc.) may be sequentially formed in the openings of the photoresist and on the exposed portions of the seed material layer. Then, the photoresist and portions of the seed material layer on which the conductive materials is not formed may be removed. A reflow process is optionally performed to shape the topmost conductive material (e.g., solder) into the desired shapes. The remaining portions of the seed material layer and the conductive materials form the first conductive bumps 101′ and/or the second conductive bumps 102′. It should be noted that other methods for forming the first conductive bumps 101′ and the second conductive bumps 102′ are possible, and are fully intended to be included within the scope of the present disclosure.

With continued reference to FIG. 1, a respective first conductive bump 101′ may include a seed layer 1011, a first metallic layer 1012 overlying the seed layer 1011, a second metallic layer 1013 overlying the first metallic layer 1012, and a third metallic layer 1014 overlying the second metallic layer 1013. The seed layer 1011 may include a first sublayer 1011a and a second sublayer 1011b overlying the first sublayer 1011a. For example, the first sublayer 1011a is a titanium sublayer and the second sublayer 1011b is a copper sublayer, although any suitable conductive seed material may be employed. The first metallic layer 1012 and the second sublayer 1011b may be formed of the same material (e.g., copper), while the first metallic layer 1012 and the overlying second metallic layer 1013 may be of different materials. The second metallic layer 1013 may be a nickel-containing layer or may include nickel, tin, tin-lead, gold, silver, platinum, palladium, Indium, nickel-palladium-gold, nickel-gold, alloys, etc. The third metallic layer 1014 may be a solder-containing layer or may include lead-free solder, such as tin, SnAg, tin bismuth (SnBi) solder, copper (SAC) solder, combinations thereof, or the like. The second metallic layer 1013 may serve as a diffusion barrier layer which blocks copper diffusion from the first metallic layer 1012 to the third metallic layer 1014. For example, without the diffusion barrier layer, an intermetallic compound (IMC) can form at the interface with the solder layer with an abundant copper source from the first metallic layer 1012, and the result is weak strength and poor adhesion.

In some embodiments, a respective second conductive bump 102′ includes a seed layer 1021 including a first sublayer 1021a and a second sublayer 1021b, a first metallic layer 1022 overlying the seed layer 1021, a second metallic layer 1023 overlying the first metallic layer 1022, and a third metallic layer 1024 overlying the second metallic layer 1023. Each layer of the respective second conductive bump 102′ may be similar to the corresponding layer of the respective first conductive bump 101′, and thus the detailed descriptions are not repeated for the sake of brevity. In some embodiments, a pitch P1 between two adjacent first conductive bumps 101′ is less than a pitch P2 between two adjacent second conductive bumps 102′. For example, the pitch P1 is less than 20 μm, and the pitch P2 is multiple times greater than the pitch P1, such as about 80 μm to 90 μm. In some embodiments, a maximum lateral dimension (e.g., a diameter or a width) D1 of a respective first conductive bump 101′ is less than a maximum lateral dimension (e.g., a diameter or a width) D2 of a respective second conductive bump 102′. It should be noted that the illustration of FIG. 1 is an example, and the number and the configuration of the first and second conductive bumps 101′ and 102′ may vary depending on the product requirements.

Referring to FIG. 2 and with reference to FIG. 1, first IC dies 110 may be disposed on and electrically coupled to the first and second conductive bumps 101′ and 102′. The respective first IC die 110 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), a combination thereof (e.g., a system-on-a-chip (SoC) die), and/or the like. These first IC dies 110 may be of different types. For example, the first IC die 110A is a logic die and the first IC die 110B is a memory die. In some embodiments, all of the first IC dies 110 are of a same type.

The first IC dies 110 may be formed in a single wafer or multiple wafers, and the wafer may include different die regions that are singulated to form individual first IC dies 110. For example, the respective first IC die 110 includes a semiconductor substrate 111, such as silicon, doped or undoped, or an active layer of a semiconductor-on-insulator (SOI) substrate. The semiconductor substrate 111 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the semiconductor substrate 111 includes devices (e.g., capacitors, diodes, transistors, resistors, inductors, etc.; not shown), an interconnect structure (not shown) including alternating dielectric layers and conductive layers and connected to the devices to form functional circuitry.

The respective first IC die 110 may include die connectors 112 distributed over the semiconductor substrate 111 and connected to the interconnect structure (if exists). The die connectors 112 of the respective first IC die 110 may include first connectors 1121 and second connectors 1122. The first and second connectors 1121 and 1122 of the first IC dies 110A and 110B may be arranged in a mirror-symmetrical configuration with respective to a virtual axis between the first IC dies 110A and 110B in the cross-sectional view. The arrangement of the array of the first and second connectors 1121 and 1122 of the first IC die 110A may essentially be mapped on the first IC die 110B by reflection, vice versa. For example, the first connectors 1121 of the first IC die 110A are disposed within the right part of the lateral extent of the semiconductor substrate 111 and the second connectors 1122 of the first IC die 110A are disposed within the left part, while the first connectors 1121 of the first IC die 110B are disposed within the left part of the lateral extent of the semiconductor substrate 111 and the second connectors 1122 of the first IC die 110B are disposed within the right part.

The first and second connectors 1121 and 1122 may be similar to the first and second conductive bumps 101′ and 102′ described in FIG. 1, respectively. For example, the pitch of the first connectors 1121 is substantially equal to the pitch P1, and the pitch of the second connectors 1122 is substantially equal to the pitch P2, where the pitch P1 is less than the pitch P2. Although respective layers of the respective die connectors 112 are not individually labeled in the drawings, each of the first and second connectors 1121 and 1122 may include a seed layer, a first metallic layer, a second metallic layer, and a third metallic layer sequentially formed over the semiconductor substrate 111. For example, the respective first IC die 110 is picked and placed on the first and second conductive bumps 101′ and 102′ and then the die connectors 112 are bonded to the first and second conductive bumps 101′ and 102′ through a thermal compression bonding process or any suitable technique. For example, the heat is applied to the structure until the third metallic layer of the respective first connector 1121 and the third metallic layer 1014 of corresponding one of the first conductive bumps 101′ are melted and joined together, and then the joined bumps are cool down to solidify so as to form a respective first conductive joint 111J. Similarly, the third metallic layer of the respective second connector 1122 and the third metallic layer 1024 of corresponding one of the second conductive bumps 102′ are heated and joined together to form a respective second conductive joint 112J. For example, the first and second conductive joints 111J and 112J are solder joints. Accordingly, the first connectors 1121 are bonded to respective ones of the first conductive bumps 101′, and the second connectors 1122 are bonded to respective ones of the second conductive bumps 102′.

With continued reference to FIG. 2, a first underfill 121 may be formed over the first temporary carrier 51 to surround the first and second conductive joints 111J and 112J, the die connectors 112 of the respective first IC die 110, and the first and second conductive bumps 101′ and 102′. The first underfill 121 may include a liquid epoxy. For example, the underfill material is dispensed onto the first temporary carrier 51 adjacent to the first IC dies 110, which then starts to spread out and move by capillary forces to fill the gap between the first IC dies 110 and the first and second conductive bumps 101′ and 102′, and then the underfill material is cured to harden so as to form the first underfill 121. The first underfill 121 may climb upward to cover at least a portion of the sidewalls 110s of one or more first IC dies 110. In some embodiments, the sidewall of each of the first and second conductive joints 111J and 112J is a convex sidewall projecting toward the first underfill 121. The left portion of the first underfill 121 covering the first IC die 110A may (or may not) be continuously connected to the right portion of the first underfill 121 covering the first IC die 110B, depending on the applied amount of the underfill material and the spacing between adjacent first IC dies 110. Alternatively, the first underfill 121 is omitted.

Still referring to FIG. 2, a first insulating encapsulant 131 may be formed over the first temporary carrier 51 to laterally cover the first underfill 121 and the exposed portions of the first IC dies 110. The first insulating encapsulant 131 may include an epoxy resin, a molding underfill, an organic polymer, a polymer with (or without) fillers, or any suitable insulating material, and may be formed by compressive molding, transfer molding, or any suitable methods. In some embodiments where the first underfill is not formed, a molding underfill material is used as the first insulating encapsulant 131, and the molding underfill material fills the space which was filled by the first underfill. In some embodiments, a planarization process is performed to level the first insulating encapsulant 131 and the first IC dies 110. The planarization process may include chemical mechanical polishing (CMP), grinding, etching, a combination thereof, or the like. The first surface 131a of the first insulating encapsulant 131 may be substantially leveled (or coplanar) with the rear surfaces 110r of the first IC dies 110 (e.g., the rear surfaces 111r of the semiconductor substrates 111), within the process variations.

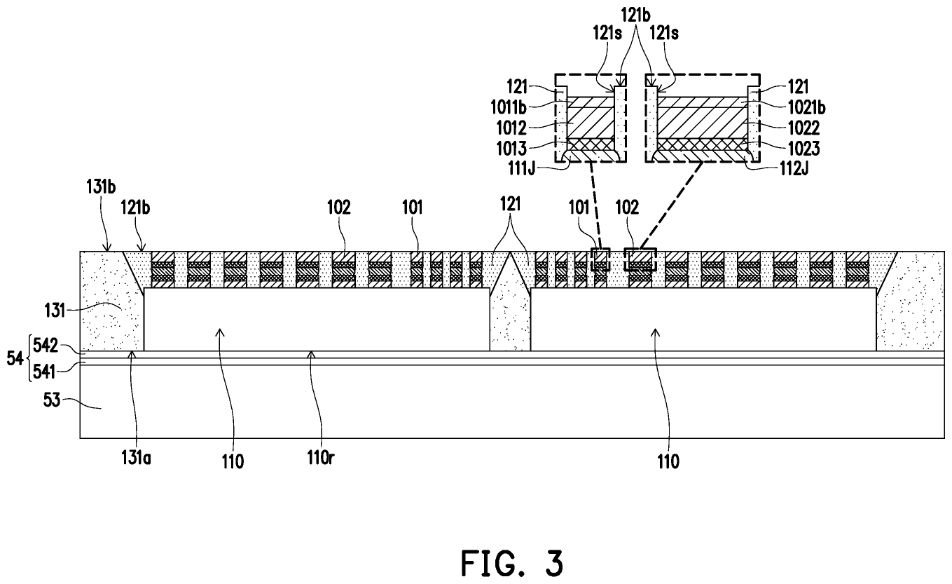

Referring to FIG. 3 and with reference to FIG. 2, the resulting structure shown in FIG. 2 may be flipped over, and the first surface 131a of the first insulating encapsulant 131 and the rear surfaces 110r of the first IC dies 110 may be attached to a second temporary carrier 53 through, e.g., a second release layer 54. The second temporary carrier 53 may be similar to the first temporary carrier 51 described in FIG. 1. The second release layer 54 may include sublayers such as a LTHC film 541 and an adhesive film 542 overlying the LTHC film 541. Alternatively, the second release layer 54 is a single layer (e.g., a LTHC film or a die attach film). The first temporary carrier 51 may be removed by de-bonding the first release layer 52. For example, where the first release layer 52 is the LTHC layer, suitable light illumination, e.g., an ultra-violet (UV) light, a laser, etc., may be applied to weaken the bonds of the LTHC material such that the first temporary carrier 51 may be separated from the remaining structure. In some embodiments where the first release layer 52 is the adhesive, a suitable solvent may be used to dissolve the first release layer 52, thereby removing the first temporary carrier 51 from the overlying structure. Alternatively, the removal process of the first temporary carrier 51 and the first release layer 52 includes mechanical peeling, grinding, etching, and may include additional cleaning process. After the removing process, the first insulating encapsulant 131, the first underfill 121, the first and second conductive bumps 101′ and 102′ may be accessibly revealed. For example, a second surface 131b of the first insulating encapsulant 131 (e.g., opposite to the first surface 131a) and a surface 121b of the first underfill 121 are substantially leveled (or coplanar), within process variations.

With continued reference to FIG. 3 and with reference to FIG. 1, a portion of each of the first and second conductive bumps 101′ and 102′ may be removed to form a respective first conductive bump 101 and a respective second conductive bump 102. As shown in the enlarged views, the first and second conductive bumps 101 and 102 are recessed from the surface 121b of the first underfill 121, and the inner sidewalls 121s of the first underfill 121 may be accessibly revealed. For example, at least the first sublayer 1011a of the respective seed layer 1011 and at least the first sublayer 1021a of the respective seed layer 1021 are removed by an etching process while a photomask (not shown) protects the first underfill 121 and the first insulating encapsulant 131 from etching, and then the photomask is removed after the etching. For example, a selective etching process is performed to remove the first sublayers 1011a and 1021a (e.g., a titanium layer), and the underlying second sublayers 1011b and 1021b may remain substantially intact. Alternatively, the second sublayers 1011b and 1021b may also be etched to reveal the underlying first metallic layers 1012 and 1022.

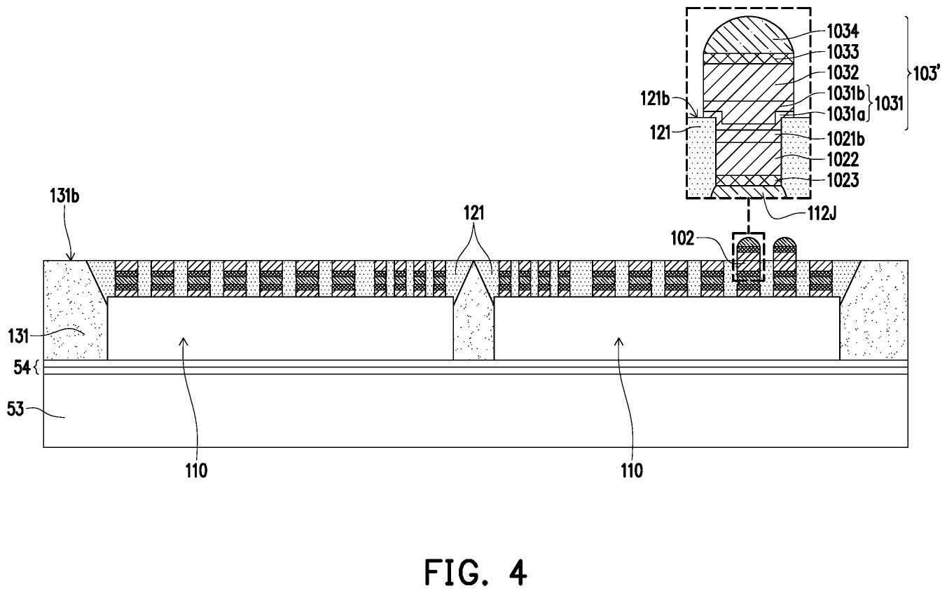

Referring to FIG. 4 and with reference to FIG. 3, a plurality of metallic layers may be sequentially formed on a certain group of the second conductive bumps 102 to form third conductive bumps 103′. For example, a seed layer 1031 is formed on the exposed surface of the second sublayer 1021b. The seed layer 1031 may include a first sublayer 1031a (e.g., a titanium film) and a second sublayer 1031b (e.g., a copper film) overlying the first sublayer 1031a. Alternatively, the seed layer 1031 is a single layer formed of copper or copper alloys. For example, a material layer of the first sublayer 1031a is conformally formed on the second surface 131b of the first insulating encapsulant 131, the surface 121b and the inner sidewall 121s of the first underfill 121, and the exposed surface of the second sublayer 1021b, and then a material layer of the second sublayer 1031b is formed on the material layer of the first sublayer 1031a. Next, a photoresist (not shown) having openings may be formed on the material layer of the second sublayer 1031b. A first metallic layer 1032 (e.g., a copper layer), a second metallic layer 1033 (e.g., a nickel layer), and a third metallic layer 1034 (e.g., a solder layer) may be sequentially formed in the openings of the photoresist and on the exposed portions of the seed material layer directly above the certain group of the second conductive bumps 102. Then, the photoresist and portions of the seed material layer on which those metallic layers is not formed may be removed. A reflow process is optionally performed to shape the third metallic layer 1034 into the desired shape. The remaining portions of the seed material layer and the overlying metallic layers may form the third conductive bumps 103′. It should be noted that other methods for forming the third conductive bumps 103′ are possible, and are fully intended to be included within the scope of the present disclosure.

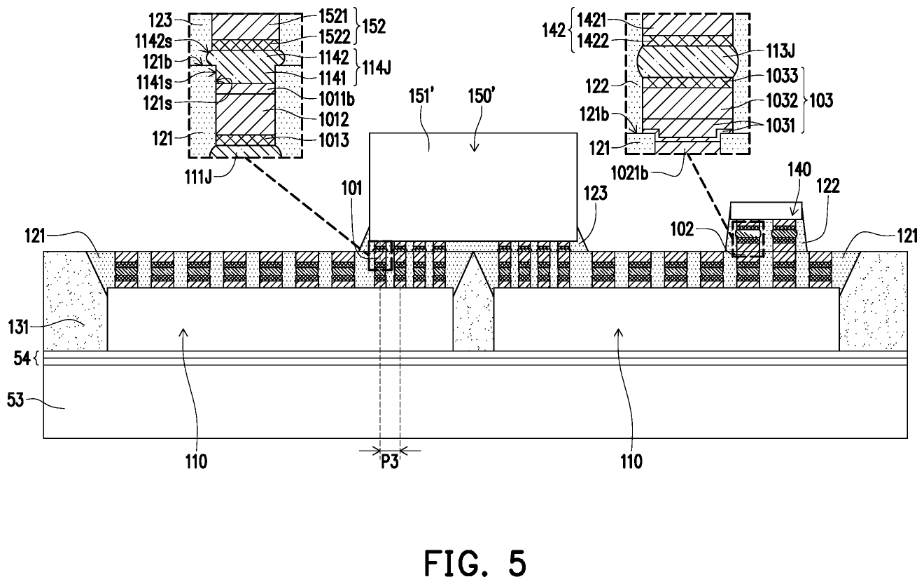

Referring to FIG. 5 and with reference to FIG. 4, a passive device 140 is optionally attached to the third conductive bumps 103′ through, e.g., a pick-and-place process followed by a reflow process or any suitable method. The passive device 140 may be or may include an integrated passive device (IPD), a surface mount device (SMD), a passive component (e.g., a capacitor, an inductor, a resistor, or the like), etc. For example, the passive device 140 includes die connectors 142, and the respective die connector 142 includes a first metallic layer 1421, a second metallic layer 1422 overlying the first metallic layer 1421, and a third metallic layer (not individually shown; e.g., a solder layer) overlying the second metallic layer 1422. The third metallic layer and the third metallic layer 1034 may be joined together through, e.g., reflowing or the like, to form a third conductive joint 113J. Alternatively, forming the third conductive bumps 103 and attaching the passive device 140 to the third conductive bumps 103 are skipped. In some embodiments, a second underfill 122 is formed in a gap between the passive device 140 and the surface 121b of the first underfill 121 to surround the die connectors 142, the third conductive joints 113J, and the third conductive bumps 103. The second underfill 122 may be similar to the first underfill 121. In some embodiments, the sidewall of the respective third conductive joints 113J is a convex sidewall protruded toward the second underfill 122. Alternatively, the second underfill 122 is omitted.

In some embodiments, at least one second IC die 150′ is attached to the first conductive bumps 101 through, e.g., pick-and-place by thermal compressive bonding or the like. The second IC die 150′ may provide electrical routing and connection between the first IC dies 110. For example, the second IC die 150′ is referred to as an interconnecting die, a bridge die, or a local interconnect component. The second IC die 150′ may increase the communication bandwidth between the first IC dies 110 while maintaining low contact resistance and high reliability. The second IC die 150′ may be attached to the first conductive bumps 101 after coupling the passive device 140 to the third conductive bumps 103′. Alternatively, the bonding of the second IC die 150′ is performed prior to the bonding of the passive device 140.

The second IC die 150 may include a semiconductor substrate 151′ and die connectors 152 distributed over the semiconductor substrate 151′. The semiconductor substrate 151′ may be similar to the semiconductor substrate 111 described in FIG. 1. The semiconductor substrate 151′ may include devices (e.g., capacitors, diodes, transistors, resistors, inductors, etc.) or may be free of devices. The die connectors 152 may be provided at a pitch P3 (e.g., less than 20 μm), which may be substantially equal to the pitch P1 of the first conductive bumps 101′ (see FIG. 1). The respective die connector 152 may include a first metallic layer 1521, a second metallic layer 1522 overlying the first metallic layer 1521, and a third metallic layer (not individually shown; e.g., a solder layer) overlying the second metallic layer 1522. The second metallic layer 1522 may be omitted, in some embodiments. The third metallic layer may be disposed over the second sublayers 1011b of the corresponding first conductive bumps 101, and a reflow process may be performed on the third metallic layer to form a fourth conductive joint 114J bonding the die connector 152 to the corresponding first conductive bump 101.

With continued reference to FIG. 5, the respective fourth conductive joint 114J may include a first portion 1141 physically connected to the first conductive bump 101 and a second portion 1142 overlying the first portion 1141 and physically connected to the die connector 152. The first portion 1141 may be laterally covered by the first underfill 121 and have a substantially vertical sidewall 1141s adjoining the inner sidewall 121s of the first underfill 121. The second portion 1142 may be protruded upward from the first underfill 121 and may have a curved sidewall 1142s connected to the substantially vertical sidewall 1141s. A third underfill 123 is optionally formed in a gap between the second IC die 150′ and the surface 121b of the first underfill 121 to surround the die connectors 152, the fourth conductive joints 114J, and the first conductive bumps 101. The third underfill 123 may be similar to the second underfill 122 and may (or may not) be formed at a same step of forming the second underfill 122. The third underfill 123 laterally covers the second portion 1142 of the respective fourth conductive joint 114J, and the curved sidewall 1142s of the second portion 1142 may be a convex sidewalls projecting toward the third underfill 123. For example, the third underfill 123 is formed on the surface 121b of the first underfill 121 and climbs upward to cover at least a portion of the semiconductor substrate 151′. Alternatively, the third underfill 123 is omitted.

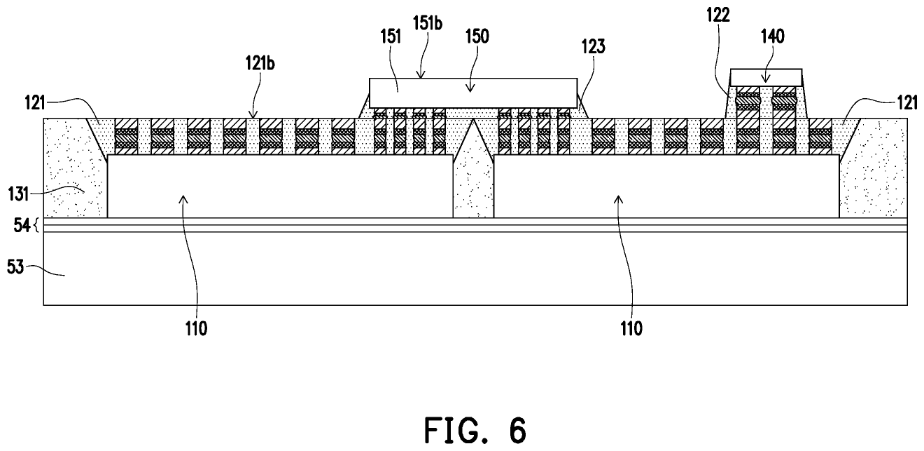

Referring to FIG. 6 and with reference to FIG. 5, a thinning process (e.g., CMP, grinding, or the like) may be performed on the second IC die 150′ to reduce the overall thickness so as to form the second IC die 150 having a rear surface 151b of the semiconductor substrate 151. For example, the maximum height of the second IC die 150 on the surface 121b of the first underfill 121 is less than the maximum height of the passive device 140 on the surface 121b of the first underfill 121. Alternatively, the maximum height of the second IC die 150 on the surface 121b of the first underfill 121 is greater than or substantially equal to the maximum height of the passive device 140 on the surface 121b of the first underfill 121. In some embodiments, the thinning process of the second IC die is skipped.

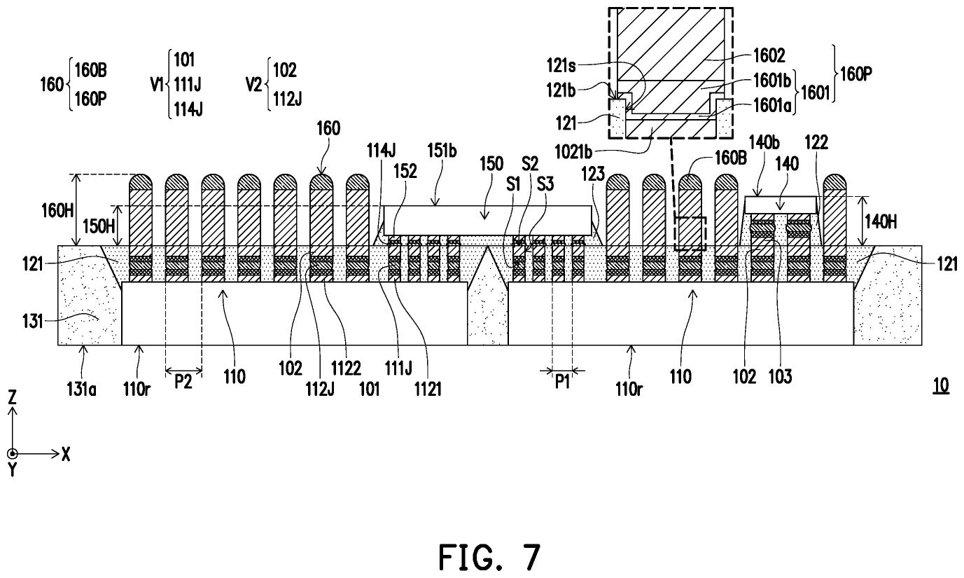

Referring to FIG. 7 and with reference to FIG. 6, electrical connectors 160 may be formed on the rest portion of the second conductive bumps 102 and surround the second IC die 150. A portion of the electrical connectors 160 may be disposed between the second IC die 150 and the passive device 140 and may surround the passive device 140. In some embodiments, the electrical connectors 160 include micro-bumps, ball grid array (BGA) connectors, solder balls, metal pillars, controlled collapse chip connection (C4) bumps, electroless nickel-electroless palladium-immersion gold (ENEPIG) technique formed bumps, or the like. The electrical connectors 160 may include a conductive material such as solder, copper, aluminum, gold, nickel, silver, palladium, tin, the like, or a combination thereof. In some embodiments, the respective electrical connector 160 includes a pillar portion 160P and a bump portion 160B overlying the pillar portion 160P, where the pillar portions 160P and the bump portions 160B may be made of different conductive materials. For example, the pillar portions 160P include copper, copper alloy, etc., and the bump portions 160B include solder material.

In some embodiments, the respective electrical connector 160 is formed by initially forming a first sublayer of a seed material conformally on the second conductive bump 102 and the first underfill 121, forming a second sublayer of the seed material on the first sublayer, forming a patterned photoresist on the second sublayer, plating a first metallic layer in the openings of the patterned photoresist, optionally forming a second metallic layer (not shown), forming a solder material, removing the patterned photoresist, removing excess portions of the seed material on which the first metallic layer is not formed, optionally reflowing the solder material to form the bump portion 160B. The remaining portion underlying the bump portion 160B forms the pillar portion 160P. For example, the pillar portion 160P at least includes a seed layer 1601 and a first metallic layer 1602 overlying the seed layer 1601, where the seed layer 1601 includes a first sublayer 1601a conformally covering the surface 121b and the inner sidewall 121s of the first underfill 121 and the exposed surface of the second conductive bump 102, the seed layer 1601 further includes a second sublayer 1601b (e.g., copper layer) overlying the first sublayer 1601a. In some embodiments, a height 160H measured from the highest point of the bump portion 160B of the respective electrical connector 160 to the surface 121b of the first underfill 121 is greater than a height 150H measured from the thinned rear surface 151b of the second IC die 150 to the surface 121b of the first underfill 121. In some embodiments, the height 160H is greater than a height 140H measured from the rear surface 140b of the passive device 140 to the surface 121b of the first underfill 121.

With continued reference to FIG. 7 and FIG. 6, the second temporary carrier 53 may be removed by, e.g., de-bonding the second release layer 54. For example, suitable light illumination may be applied to the second release layer 54 to separate the second temporary carrier 53 from the remaining structure, a suitable solvent may be used to dissolve the second release layer 54 to remove the separate the second temporary carrier 53 from the remaining structure, or other suitable removal method (e.g., a mechanical peel-off process, a grinding process, or an etching process, etc.) may be used to remove the second temporary carrier 53. After removing the second temporary carrier 53 and the second release layer 54, the first surface 131a of the first insulating encapsulant 131 and the rear surfaces 110r of the first IC dies 110 may be accessibly revealed. In some embodiments, the first surface 131a of the first insulating encapsulant 131 and the rear surfaces 110r of the first IC dies 110 are substantially leveled (or coplanar), within process variations. A singulation process is optionally performed to dice the resulting structure into individual semiconductor devices 10. The semiconductor devices 10 may then be bonded to a package component (e.g., an interposer, a package substrate, a printed circuit board, a package structure, and/or the like; not shown).

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Still referring to FIG. 7, the semiconductor device 10 may include the second IC die 150 stacked upon and electrically coupled to the first IC dies 110. The respective die connector 152 of the second IC die 150 may be electrically coupled to the corresponding first connector 1121 of the respective first IC die 110 through the first conductive bump 101, the first conductive joint 111J, and the fourth conductive joints 114J. The first conductive joint 111J, the first conductive bump 101, and the fourth conductive joints 114J collectively provide an electrical interconnection in the vertical axis of the semiconductor device 10 and may be collectively viewed as a conductive feature or a first electrical connection V1. The first electrical connection V1 may have the first conductive bump 101 having the substantially vertical sidewall S3, the first conductive joint 111J formed on the first side S1 of the first conductive bump 101 and having the curved sidewall, and the fourth conductive joints 114J formed on the second side S2 of the first conductive bump 101 and having the curved sidewall.

The respective electrical connector 160 may be electrically coupled to the corresponding second connector 1122 of the respective first IC die 110 through the second conductive joint 112J and the corresponding second conductive bump 102, where the second conductive joint 112J and the second conductive bump 102 collectively provide an electrical interconnection in the vertical axis of the semiconductor device 10 and may be collectively viewed as a conductive feature or a second electrical connection V2. For example, the pitch P1 of the first electrical connection V1 is less than the pitch P2 of the second electrical connection V2, where the first electrical connection V1 provides the fine-pitched interconnection. Each of the first electrical connection V1 and the second electrical connection V2 may be viewed as a signal line routed in the Z-direction between the first IC dies 110 and the second IC die 150. The signal paths between the second IC die 150 and the first IC dies 110 and between the electrical connectors 160 and the first IC dies 110 are shorter than those in a conventional semiconductor device in which stacked dies and electrical connectors are coupled together using redistribution layers which have signal lines routed in the X-direction, the Y-direction, and the Z-direction. The fabrication costs may be reduced by omitting the redistribution layers between stacked IC dies.

The first conductive bumps 101 coupling the second IC die 150 to the first IC dies 110 may have a fine pitch which substantially matches a pitch of the die connectors 152 of the second IC die 150 and a pitch of the first connectors 1121 of the first IC dies 110. To achieve the fine-pitched configuration of the first conductive bumps 101, the shift of the first IC dies 110 due to the formation of the first insulating encapsulant 131 may be taken into consideration when forming the first conductive bumps 101 at the very beginning (see FIG. 1). For example, the calibrated data of the shift may be produced using simulation and/or experimental methods. The first conductive bumps 101 may be formed with an offset to compensate for the expected shift based on the calibrated data.

It is appreciated that as pitches between die connectors of the IC dies decrease, overlay control becomes more difficult because the overlay shift may degrade device performance and/or cause reliability issues. By recessing the first conductive bump 101 from the surface 121b of the first underfill 121 (see the enlarged view in FIG. 3), the first portion 1141 of the respective fourth conductive joint 114J may be physically coupled to the first conductive bump 101 and confined by the first underfill 121, thereby limiting the overlay offset and reducing misalignment. In this manner, an overlay offset of the first conductive bump 101 and the corresponding die connector 152 may be about +/−1 μm. Similarly, the respective second conductive bump 102 is recessed from the surface 121b of the first underfill 121, the corresponding electrical connector 160 may respectively have a portion inserted into the first underfill 121 to be in physical contact with the second conductive bump 102, thereby limiting the overlay offset and achieving better electrical performance. In this manner, an overlay offset of the second conductive bump 102 and the corresponding electrical connector 160 may be about +/−2 μm.

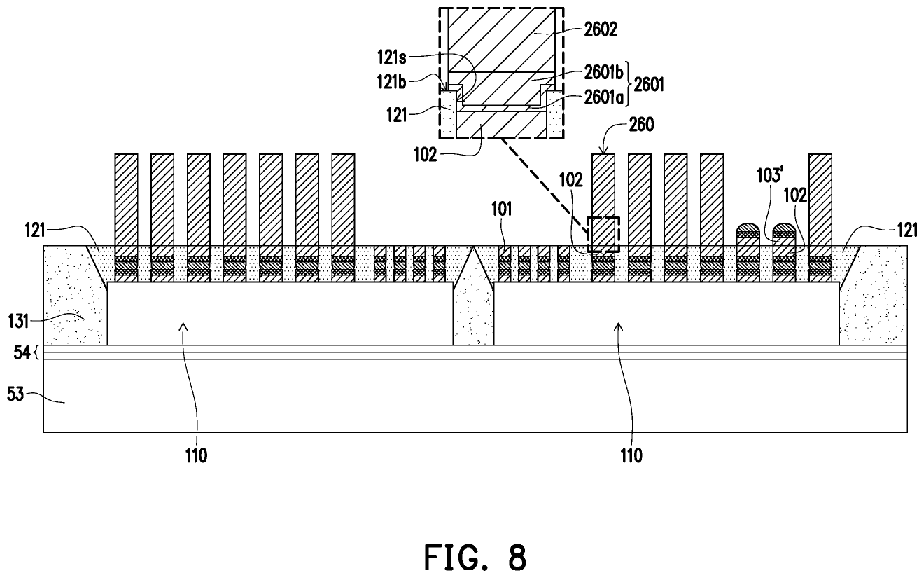

FIGS. 8-9, 10A, and 11A illustrate schematic cross-sectional views of intermediate steps during a process for forming a semiconductor device, in accordance with some embodiments. Unless specified otherwise, like reference numerals in this embodiment represent like components in the embodiment shown in FIGS. 1 through 7 formed by like processes, and only differences will be the focus of the following discussion. Accordingly, the processes and applicable materials may not be repeated herein.

Referring to FIG. 8 and with reference to FIG. 4, the structure in FIG. 8 is similar to the structure shown in FIG. 4, except that conductive pillars 260 may be formed on the rest portion of the second conductive bump 102. In some embodiments, a height of the respective conductive pillar 260 is greater than that of the respective third conductive bump 103′. For example, the respective conductive pillar 260 may include a seed layer 2601 and a metallic layer 2602 overlying the seed layer 2601. The seed layer 2601 may include a first sublayer 2601a (e.g., a titanium layer) conformally covering the surface 121b and the inner sidewall 121s of the first underfill 121 and the exposed surface of the second conductive bump 102. The seed layer 2601 may include the second sublayer 2601b (e.g., a copper layer) overlying the first sublayer 2601a. The metallic layer 2602 may include copper or copper alloy and may be formed by plating. Although any suitable conductive material and deposition process may be utilized to form the conductive pillars 260.

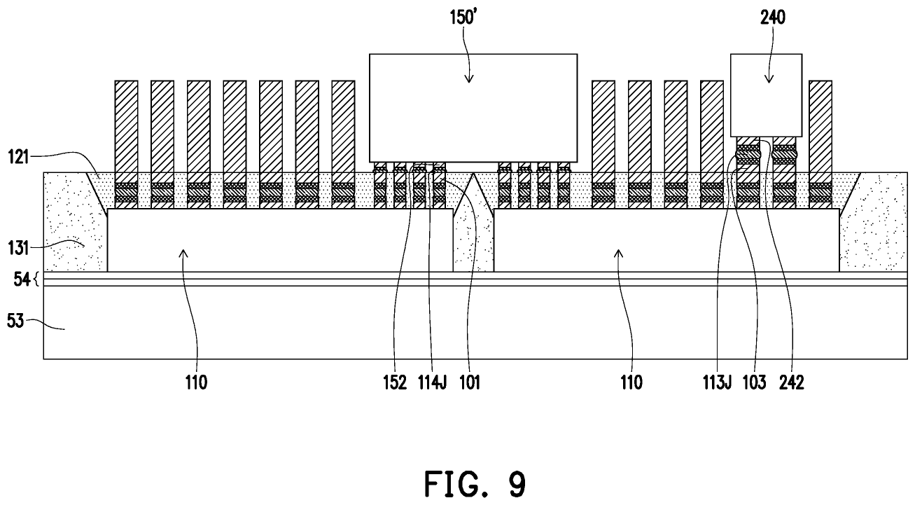

Referring to FIG. 9 and with reference to FIG. 8 and FIG. 5, a passive device 240 may be coupled to the third conductive bumps 103′, and the second IC die 150′ may be coupled to the first conductive bumps 101. For example, die connectors 242 of the passive device 240 and the third conductive bumps 103 are coupled together through the third conductive joints 113J, and the die connectors 152 of the second IC die 150 and the first conductive bumps 101 are coupled together through the fourth conductive joints 114J. The processes of coupling the passive device 240 to the third conductive bumps 103′ and coupling the second IC die 150′ to the first conductive bumps 101 may be similar to the processes described in FIG. 5. The passive device 240 may be similar to the passive device 140, except that the passive device 240 may have a greater thickness, such as greater than 90 μm.

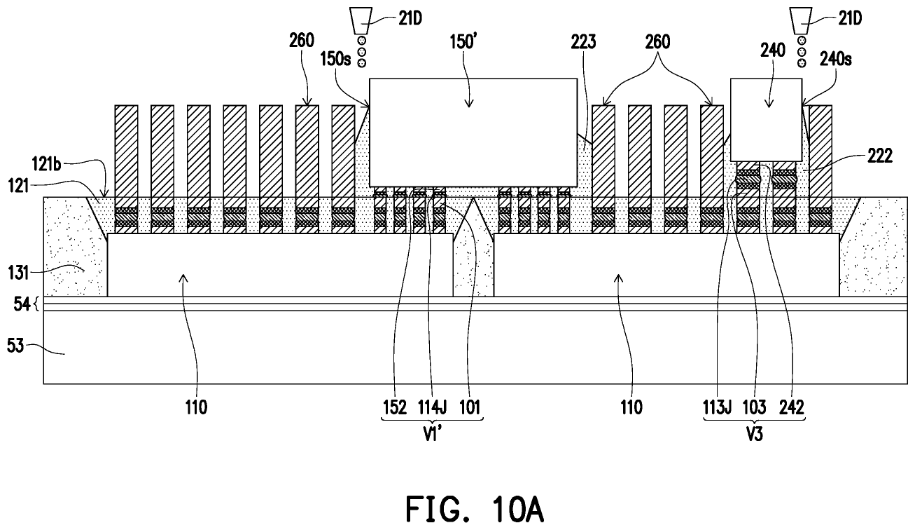

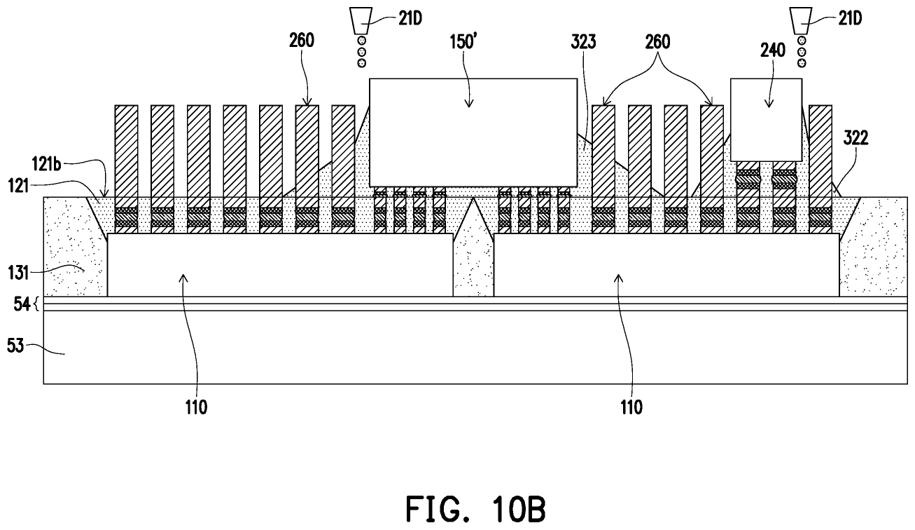

Referring to FIG. 10A and with reference to FIG. 9, a second underfill 222 may be formed on the surface 121b of the first underfill 121 to surround the die connectors 242, the third conductive bumps 103, and the third conductive joints 113J. The die connectors 242, the third conductive bumps 103, and the third conductive joints 113J may be collectively viewed as a third electrical connection V3. In some embodiments, the second underfill 222 may climb upward to at least partially cover the sidewall 240s of the passive device 240 and may extend continuously between the third electrical connection V3 and the neighboring conductive pillars 260 adjacent the third electrical connection V3. In the illustrated embodiment, the neighboring conductive pillars 260 which are two conductive pillars 260 closest to the passive device 240 have sidewalls being in physical contact with the second underfill 222. Depending on the applied amount of the underfill material, the second underfill 222 may extend further to be interposed between conductive pillars 260 as will be described later in FIG. 10B.

In some embodiments, a third underfill 223 is formed on the surface 121b of the first underfill 121 to surround the die connectors 152, the first conductive bumps 101, and the fourth conductive joints 114J. The die connectors 152, the first conductive bumps 101, and the fourth conductive joints 114J may be collectively viewed as a vertical connection V1′. The third underfill 223 may climb upward to at least partially cover the sidewall 150s of the second IC die 150 and may extend continuously between the vertical connection V1′ and the neighboring conductive pillars 260 adjacent the vertical connection V1′. Similar to the second underfill 222, the third underfill 223 may be in physical contact with the sidewalls of the neighboring conductive pillars 260, and depending on the applied amount of the underfill material, the third underfill 223 may extend further as will be described later in FIG. 10B. The material of the second underfill 222 and the third underfill 223 may be similar to the first underfill 121 described in FIG. 2.

The second underfill 222 and the third underfill 223 may be formed by dispensing or any suitable deposition process. The second underfill 222 and the third underfill 223 may be formed at a same dispensing step (or different steps). For example, when forming the third underfill 223, a dispensing tool 21D is positioned above a gap between the sidewall 150s of the second IC die 150′ and one of the neighboring conductive pillars 260, and then the underfill material flows from the dispensing tool 21D to surround the vertical connections V1′ and may extend toward the neighboring conductive pillars 260. A curing process may be performed on the underfill material to solidify. In some embodiments, a coverage area of the third underfill 223 on the sidewall 150s of the second IC die 150′ proximity to the position of the dispensing tool 21D is greater than a coverage area of the third underfill 223 on an opposing sidewall 150s of the second IC die 150′. For example, in the cross section, the profile of the third underfill 223 on two opposing sidewalls 150s of the second IC die 150′ is asymmetrical, where the highest point of the profile of the third underfill 223 on one of the sidewalls 150s is higher than the highest point of the profile of the third underfill 223 on the other one of the sidewalls 150s. Similarly, the in the cross section, the profile of the second underfill 222 on two opposing sidewalls 240s of the passive device 240 is asymmetrical, where the highest point of the profile of the second underfill 222 on one of the sidewalls 240s is higher than the highest point of the profile of the second underfill 222 on the other one of the sidewalls 240s.

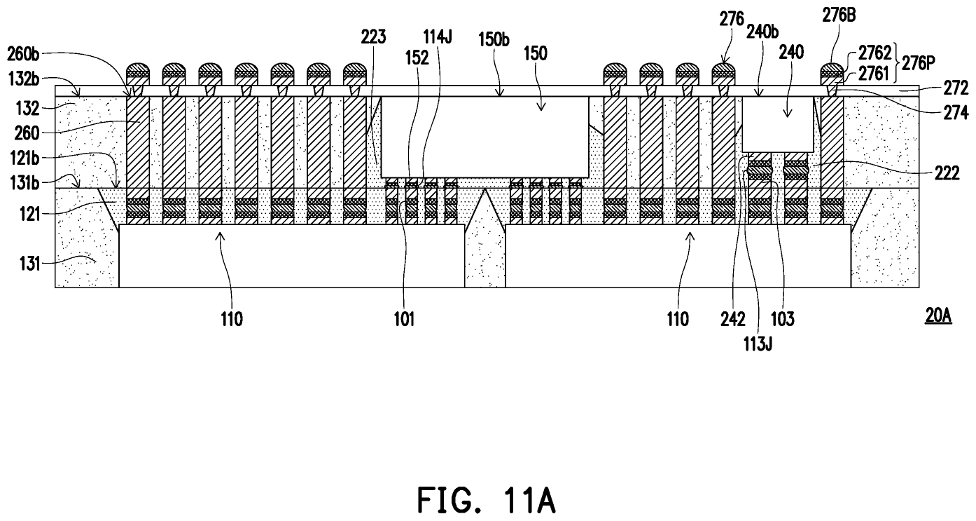

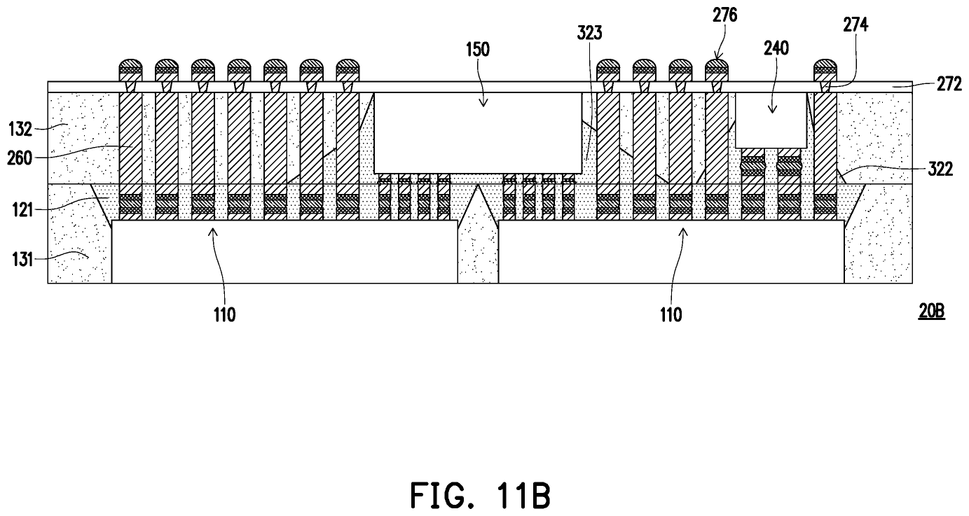

Referring to FIG. 11A and with reference to FIG. 10A, a second insulating encapsulant 132 may be formed on the second surface of the first insulating encapsulant 131 and the surface 121b of the first underfill 121 to laterally cover the conductive pillars 260, the second IC die 150, the passive device 240, the second underfill 222, and the third underfill 223. The material and the forming process of the second insulating encapsulant 132 may be similar to those of the first insulating encapsulant 131 described in FIG. 2. In some embodiments, a planarization process (e.g., CMP, grinding, etching, a combination thereof, etc.) is performed to level the conductive pillars 260, the second IC die 150, and the passive device 240. For example, the surface 132b of the second insulating encapsulant 132 is substantially leveled (or coplanar) with the surfaces 260b of the conductive pillars 260, the rear surface 150b of the second IC die 150, and the rear surface 240b of the passive device 240, within the process variations. In some embodiments, the thicknesses of the second IC die 150′ and the passive device 240 (and/or the height of the conductive pillars 260) may be reduced during the planarization process. The conductive pillars 260 may each penetrate through the second insulating encapsulant 132 and may be referred to as through insulating vias (TIVs) 260.

In some embodiments, a dielectric layer 272 is formed on the surface 132b of the second insulating encapsulant 132, the rear surface 150b of the second IC die 150, and the rear surface 240b of the passive device 240. The dielectric layer 272 may be formed of a polymeric material such as polybenzoxazole (PBO), polyimide (PI), benzocyclobutene (BCB), or other suitable material that can be patterned using lithography. In some embodiments, a conductive pattern 274 (e.g., conductive vias or under bump metallization (UBM)) is formed through the dielectric layer 272 to be in physical and electrical contact with the surfaces 260b of the conductive pillars 260. In some embodiments, electrical connectors 276 are formed on the conductive pattern 274 to be electrical coupled to the TIVs 260. The electrical connectors 276 may be micro-bumps, BGA connectors, solder balls, metal pillars, C4 bumps, ENEPIG technique formed bumps, or the like.

In some embodiments, the respective electrical connector 276 includes a pillar portion 276P and a bump portion 276B overlying the pillar portion 276P, where the pillar portions 276P and the bump portions 276B may be made of different conductive materials. For example, the bump portions 276B include solder material, and the pillar portions 276P may include a first metallic layer 2761 (e.g., a copper layer) and a second metallic layer 2762 (e.g., a nickel layer) overlying the first metallic layer 2761. Other conductive materials such as tin, silver, nickel, gold, or the like, may be used to form the electrical connectors 276. Next, the second temporary carrier 53 may be removed by de-bonding the second release layer 54. The de-bonding process of the second temporary carrier 53 may be similar to the process described in FIG. 7. As shown in FIG. 11A, a semiconductor device 20A is then provided.

FIGS. 10B and 11B illustrate schematic cross-sectional views of intermediate steps during a process for forming a further semiconductor device, in accordance with some embodiments. Unless specified otherwise, like reference numerals in this embodiment represent like components in the embodiment shown in FIGS. 8-9, 10A, and 11A formed by like processes, and only differences will be the focus of the following discussion. Accordingly, the processes and applicable materials may not be repeated herein.

Referring to FIG. 10B and with reference to FIG. 10A, the difference between the resulting structures illustrated in FIG. 10B and FIG. 10A lies in that a second underfill 322 and a third underfill 323 respectively extend further on the surface 121b of the first underfill 121 than the second underfill 222 and the third underfill 223 do. For example, the third underfill 323 not only covers the conductive pillars 260 closest to the second IC die 150′ (also called the closest conductive pillars 260 herein) but also covers at least a portion of the sidewalls of the neighboring conductive pillars 260 around the closest conductive pillars 260, depending on the dispensing amount of the underfill material supplied from the dispensing tool 21D. Similarly, the second underfill 322 may not only cover the conductive pillars 260 closest to the passive device 240 (i.e. the closest conductive pillars 260) but also covers at least a portion of the sidewalls of the neighboring conductive pillars 260 around the closest conductive pillars 260.

Referring to FIG. 11B and with reference to FIG. 10B and FIG. 11A, the second insulating encapsulant 132 may be formed to laterally cover the conductive pillars 260, the second IC die 150, the passive device 240, the second underfill 322, and the third underfill 323. The dielectric layer 272, the conductive pattern 274, and the electrical connectors 276 may be sequentially formed on the second insulating encapsulant 132 and the TIVs 260. The materials and forming processes of the second insulating encapsulant 132, the dielectric layer 272, the conductive pattern 274, and the electrical connectors 276 may be similar to those of the same component described in FIG. 11A. As shown in FIG. 11B, a semiconductor device 20B is then provided. The difference between the semiconductor device 20B and the semiconductor device 20A includes that the second underfill 322 and the third underfill 323 of the semiconductor device 20B may spread out to cover more TIVs 260 in proximity of the second IC die 150 and the passive device 240. The second insulating encapsulant 132 may cover the exposed portions of the TIVs 260, which allow the second underfill 322 and the third underfill 323 to spread out to a greater area without creating reliability issues.

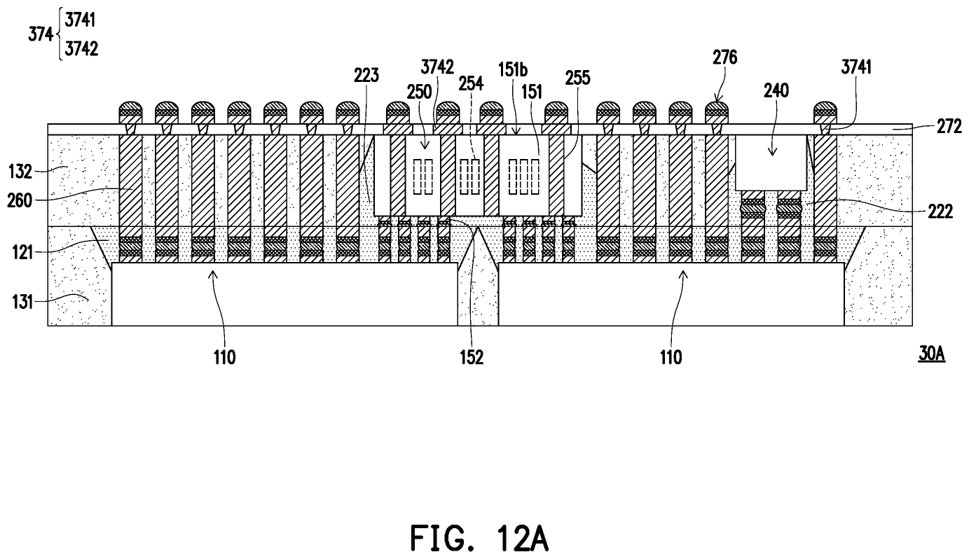

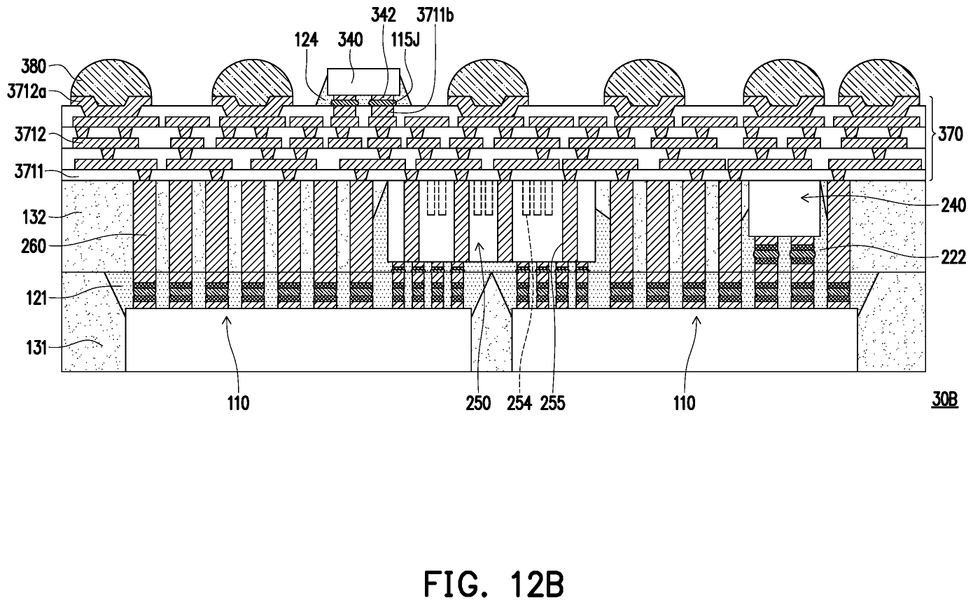

FIGS. 12A and 12B illustrate schematic cross-sectional views of variations of a semiconductor device, in accordance with some embodiments. Unless specified otherwise, like reference numerals in this embodiment represent like components in the embodiment shown in FIGS. 10A and 11A formed by like processes, and only differences will be the focus of the following discussion. Accordingly, the processes and applicable materials may not be repeated herein.

Referring to FIG. 12A and with reference to FIG. 11A, a semiconductor device 30A is similar to the semiconductor device 20A, and the difference therebetween includes that a second IC die 250 includes at least one capacitor structure 254 and may include through substrate vias (TSVs) 255. For example, the capacitor structure 254 is formed in the semiconductor substrate 151 or in the interconnect structure (not individually shown). In some embodiments, the capacitor structure 254 is the deep-trench capacitor (DTC). The capacitor structure 254 may be included in the second IC die 250 to reduce noise and stabilize signals. In some embodiments, the conductive pattern 374 formed in the dielectric layer 272 may include a first portion 3741 connected to the electrical connectors 276 and the TIVs 260 and a second portion 3742 connected to the electrical connectors 276 and the TSVs 255. The TSVs 255 may each penetrate through the semiconductor substrate 151 to provide a vertical and electrical connection between the conductive pattern 374 and the die connectors 152. Although the first portion 3741 is illustrated as via form and the second portion 3742 is illustrated as pad form, the disclosure is not limited thereto.

Referring to FIG. 12B and with reference to FIG. 12A, a semiconductor device 30B is similar to the semiconductor device 30A, and the difference therebetween includes that the semiconductor device 30B includes a redistribution structure 370 formed on the second insulating encapsulant 132, the TIVs 260, the second IC die 250, and the passive device 240. The redistribution structure 370 may include alternating stacked patterned dielectric layers 3711 and patterned conductive layers 3712. The redistribution structure 370 is shown as an example having four patterned dielectric layers 3711 and four patterned conductive layers 3712; however, more (or fewer) patterned dielectric layers and patterned conductive layers may be formed. The material(s) of the patterned dielectric layers 3711 may be or include a photo-sensitive material such as PBO, PI, BCB, a combination thereof, or the like. The material(s) of the patterned conductive layers 3712 may be or include copper, nickel, titanium, alloys, combinations thereof, or the like. The patterned conductive layers 3712 may include conductive vias, conductive lines, conductive pads, etc.

The bottommost one of the patterned conductive layers 3712 may be in physical and electrical contact with the TIVs 260. In some embodiments, the bottommost one of the patterned conductive layers 3712 is electrically coupled to the TSVs 255 of the second IC die 250. Alternatively, the TSVs 255 and/or the capacitor structure 254 may be omitted. In some embodiments, the topmost one of the patterned conductive layers 3712 includes an UBM pattern 3712a and/or conductive bumps 3712b. In some embodiments, electrical connectors 380 are formed on the UBM pattern 3712a. The electrical connectors 380 may include micro-bumps, BGA connectors, solder balls, metal pillars, C4 bumps, ENEPIG technique formed bumps, or the like. In some embodiments, at least one passive device 340 is attached to the redistribution structure 370 by coupling the die connectors 342 of the passive device 340 to the conductive bumps 3712b through fifth conductive joints 115J (e.g., solder joints). A fourth underfill 124 is optionally formed on the redistribution structure 370 to laterally cover the die connectors 342 and the fifth conductive joints 115J.

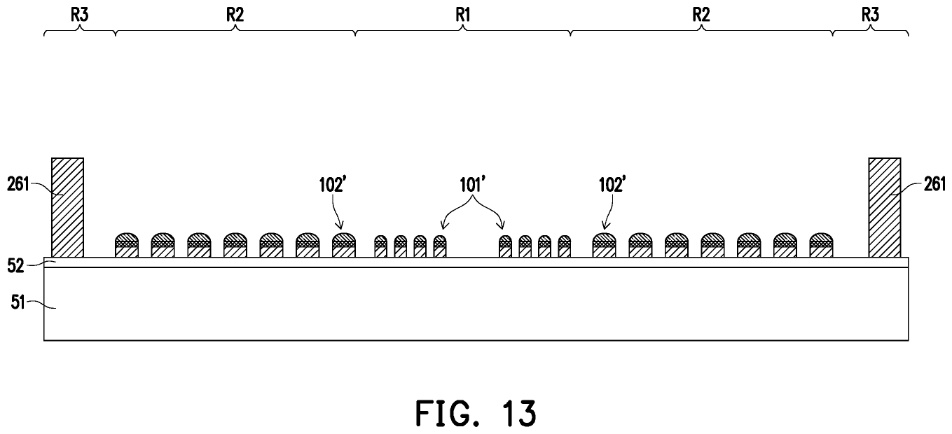

FIGS. 13 through 20 illustrate schematic cross-sectional views of intermediate steps during a process for forming a semiconductor package, in accordance with some embodiments. Unless specified otherwise, like reference numerals in this embodiment represent like components in the embodiment shown in FIGS. 1 through 7 formed by like processes, and only differences will be the focus of the following discussion. Accordingly, the processes and applicable materials may not be repeated herein.

Referring to FIG. 13 and with reference to FIG. 1, the difference between the resulting structures illustrated in FIG. 13 and FIG. 1 lies in that first conductive pillars 261 are formed in a third region R3, where the third region R3 may surround the second region R2 which surround the first region R1. In some embodiments, the first conductive pillars 261 are formed before forming the first and second conductive bumps 101′ and 102′. The first conductive pillars 261 may be higher than the first and second conductive bump 101′ and 102′. In some embodiments, the formation of the first conductive pillars 261 includes forming a seed material layer over the first temporary carrier 51, forming a patterned photoresist (not shown) on the seed material layer, plating a metallic layer in the openings of the patterned photoresist, and removing the patterned photoresist. The seed material layer may remain for forming the first and second conductive bumps 101′ and 102′, and when the patterned photoresist for forming the first and/or second conductive bumps 101′ and 102′ is removed, excess portions of the seed material layer on which the metallic layers are not formed may then be removed by, e.g., etching or the like. Alternatively, the first conductive pillars 261 are pre-formed and/or may be placed at the predetermined positions before/after forming the first and second conductive bumps 101′ and 102′.

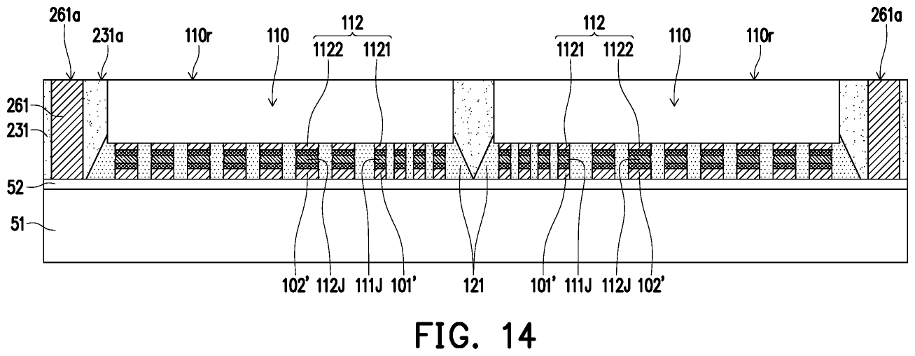

Referring to FIG. 14 and with reference to FIG. 13 and FIG. 2, the first IC dies 110 may be disposed on and electrically coupled to the first and second conductive bumps 101′ and 102′. For example, the first connectors 1121 of the respective first IC die 110 are coupled to the first conductive bumps 101′ through the first conductive joints 111J, and the second connectors 1122 of the respective first IC die 110 are coupled to the second conductive bumps 102′ through the second conductive joints 112J. The first underfill 121 is optionally formed over the first temporary carrier 51 to surround the die connectors 112, the first and second conductive joints 111J and 112J, and the first and second conductive bumps 101′ and 102′. The coupling process of the first IC dies 110 and the forming process of the first underfill 121 may be similar to the processes described in FIG. 2.

The first insulating encapsulant 231 may be formed over the first temporary carrier 51 to laterally cover the first conductive pillars 261, the first IC dies 110, and the first underfill 121. The material and the forming process of the first insulating encapsulant 231 may be similar to those of the first insulating encapsulant 131 described in FIG. 2. In some embodiments, a planarization process (e.g., CMP, grinding, etching, a combination thereof, etc.) is performed to level the first insulating encapsulant 231, the first conductive pillars 261, and the first IC dies 110. For example, a first surface 231a of the first insulating encapsulant 231 is substantially leveled (or coplanar) with first surfaces 261a of the first conductive pillars 261 and the rear surfaces 110r of the first IC dies 110, within process variations. The first conductive pillars 261 penetrating through the first insulating encapsulant 231 may be referred to as first TIVs.

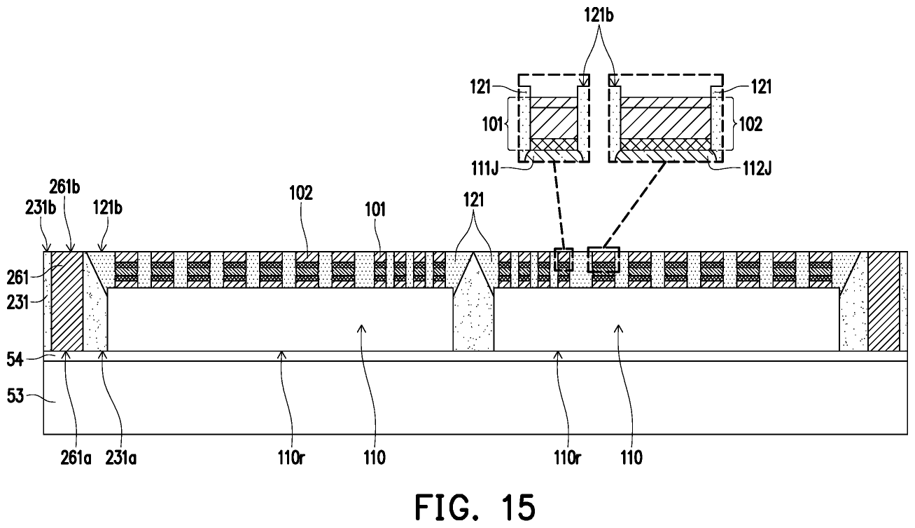

Referring to FIG. 15 and with reference to FIG. 14 and FIG. 3, the resulting structure illustrated in FIG. 14 may be flipped over, and the first surface 231a of the first insulating encapsulant 231, the first surfaces 261a of the first TIVs 261, and the rear surfaces 110r of the first IC dies 110 may be attached to the second temporary carrier 53 through, e.g., the second release layer 54. The first temporary carrier 51 may be removed by de-bonding the first release layer 52, thereby revealing the second surface 231b of the first insulating encapsulant 231, the second surfaces 261b of the first TIVs 261, and the surface 121b of the first underfill 121. The bonding of the second temporary carrier 53 and the de-bonding of the first temporary carrier 51 may be similar to the processes described in FIG. 3. In some embodiments, portions of the first and second conductive bumps 101′ and 102′ are removed to form the first and second conductive bumps 101 and 102 recessed from the surface 121b of the first underfill 121. The removing process may be similar to the process described in FIG. 3. In some embodiments, during the removal of the portions of the first and second conductive bumps 101′ and 102′, portions (e.g., the titanium sublayers of the seed layers) of the first TIVs 261 may also be removed so that the second surfaces 261b of the first TIVs 261 may be recessed from the second surface 231b of the first insulating encapsulant 231. Alternatively, during the removal of the portions of the first and second conductive bumps 101′ and 102′, the photoresist (not shown) may cover the first TIVs 261 for protection.

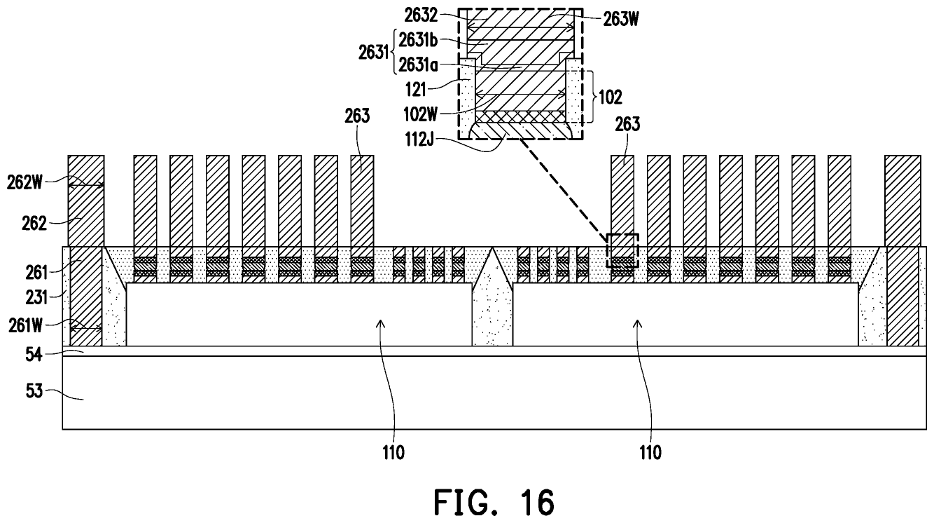

Referring to FIG. 16 and with reference to FIG. 15 and FIG. 8, second conductive pillars 262 may be formed on the first TIVs 261 and third conductive pillars 263 may be formed on the second conductive bumps 102. For example, the respective third conductive pillar 263 includes the seed layer 2631 including the first sublayer 2631a and the second sublayer 2631b, and the metallic layer 2632 overlying the seed layer 2631. The formation of the third conductive pillars 263 may be similar to the process of forming the conductive pillars 260 described in FIG. 8. The second conductive pillars 262 may be formed at a same step of forming the third conductive pillars 263. Alternatively, the second conductive pillars 262 are formed before (or after) forming the third conductive pillars 263. In some embodiments, the respective second conductive pillar 262 has a maximum lateral dimension (e.g., a width or a diameter) 262W greater than a maximum lateral dimension 261W of the underlying first TIV 261. The respective second conductive pillar 262 may be substantially aligned with the underlying first TIV 261. Alternatively, a center of the respective second conductive pillar 262 is laterally offset from that of the underlying first TIV 261. In some embodiments, the respective third conductive pillar 263 has a maximum lateral dimension (e.g., a width or a diameter) 263W greater than a maximum lateral dimension 102W of the underlying second conductive bump 102.

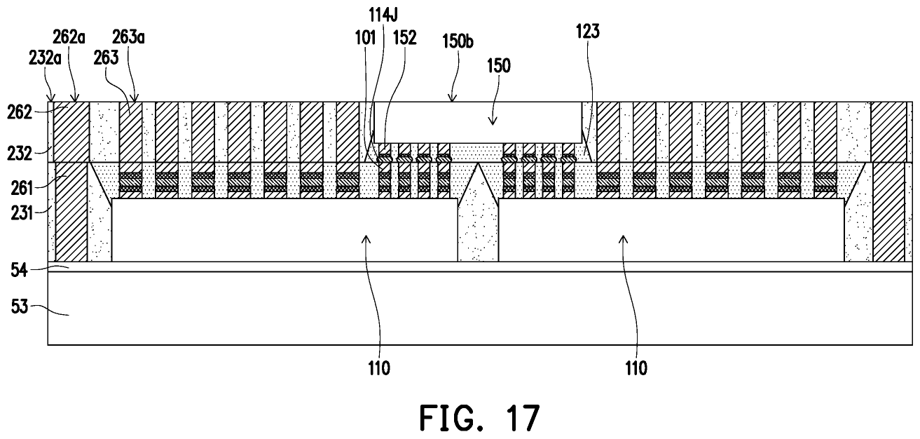

Referring to FIG. 17 and with reference to FIG. 16 and FIGS. 5-6, the second IC die 150 may be disposed on and electrically coupled to the first conductive bumps 101. For example, the die connectors 152 of the second IC die 150 are bonded to the first conductive bumps 101 through the fourth conductive joints 114J. The third underfill 123 is optionally formed to surround the die connectors 152 and the fourth conductive joints 114J. The bonding of the second IC die 150 to the first conductive bumps 101 and the formation of the third underfill 123 may be similar to the processes described in FIGS. 5-6. Next, a second insulating encapsulant 232 may be formed on the first insulating encapsulant 231 to laterally cover each of the second and third conductive pillars 262 and 263, the second IC die 150, and the third underfill 123. A portion of the second insulating encapsulant 232 may be interposed between the third underfill 123 and the neighboring third conductive pillars 263 so as to fully separate the third underfill 123 from the third conductive pillars 263. The material and the forming process of the second insulating encapsulant 232 may be similar to the first insulating encapsulant 231.

In some embodiments, a surface 232a of the second insulating encapsulant 232, a surface 262a of the second conductive pillars 262, a surface 263a of the third conductive pillars 263, and the rear surface 150b of the second IC die 150 are planarized to be substantially leveled (or coplanar) with one another, within process variations. In some embodiments, the third underfill 123 is replaced with the third underfill 223 described in FIG. 10A or the third underfill 323 described in FIG. 10B. In such cases, the neighboring third conductive pillars 263 may have an upper sidewall covered by the second insulating encapsulant 232 and a lower sidewall covered by the third underfill 223/323. The second and third conductive pillars 262 and 263 penetrating through the second insulating encapsulant 232 may be respectively referred to as second TIVs 262 and third TIVs 263.

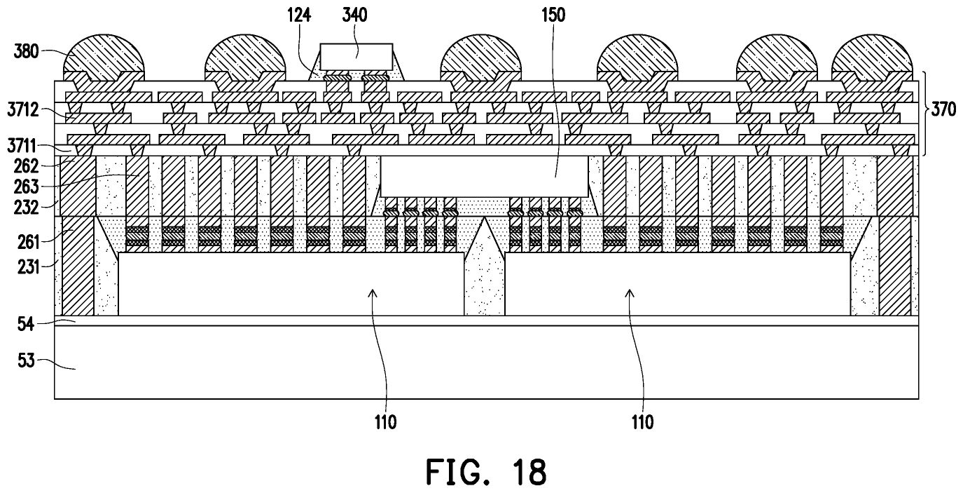

Referring to FIG. 18 and with reference to FIG. 17 and FIG. 12B, the redistribution structure 370 including the patterned dielectric layers 3711 and the patterned conductive layers 3712 may be formed on the second insulating encapsulant 232, the second and third TIVs 262 and 263, and the second IC die 150. For example, the bottommost one of the patterned dielectric layers 3711 is physically and electrically coupled to the second and third TIVs 262 and 263. In some embodiments, the passive device 340 is attached to the redistribution structure 370. The fourth underfill 124 is optionally formed in a gap between the redistribution structure 370 and the passive device 340. In some embodiments, the electrical connectors 380 are formed on the topmost one of the patterned conductive layers 3712 and surround the passive device 340. The forming process of the redistribution structure 370, the attachment of the passive device 340, and the forming process of the electrical connectors 380 may be similar to the processes described in FIG. 12B.

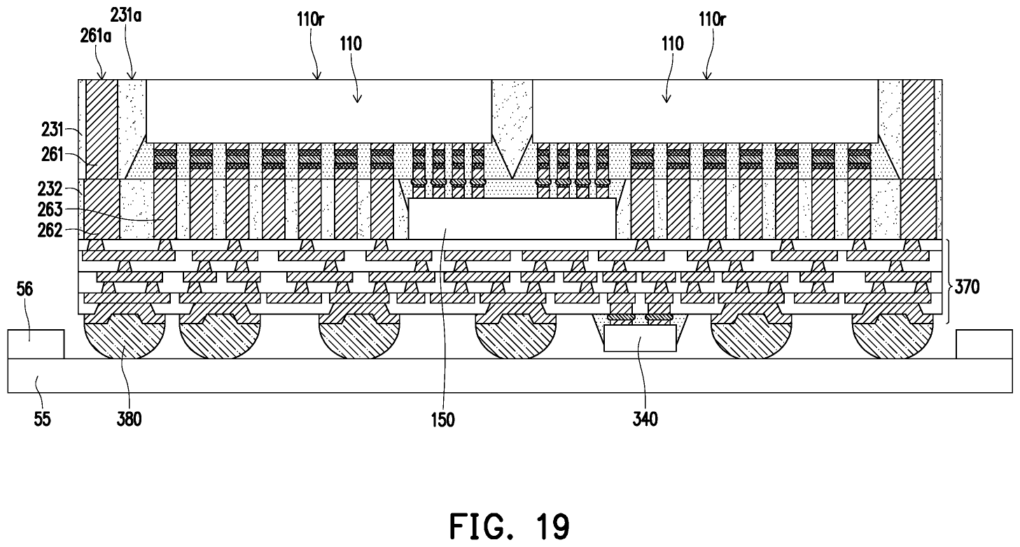

Referring to FIG. 19 and with reference to FIG. 18, the second temporary carrier 53 may be removed by, e.g., de-bonding the second release layer 54. The de-bonding process of the second temporary carrier 53 may be similar to the process described in FIG. 7. Once the second temporary carrier 53 and the second release layer 54 are removed, the first surface 231a of the first insulating encapsulant 231, the first surfaces 261a of the first TIVs 261, and the rear surfaces 110r of the first IC dies 110 may be accessibly revealed. The resulting structure may be flipped over, and the electrical connectors 380 may be attached to a tape 55 supported by a frame 56 for further processing. The tape 55 may be a dicing tape and the frame 56 may be a dicing frame.

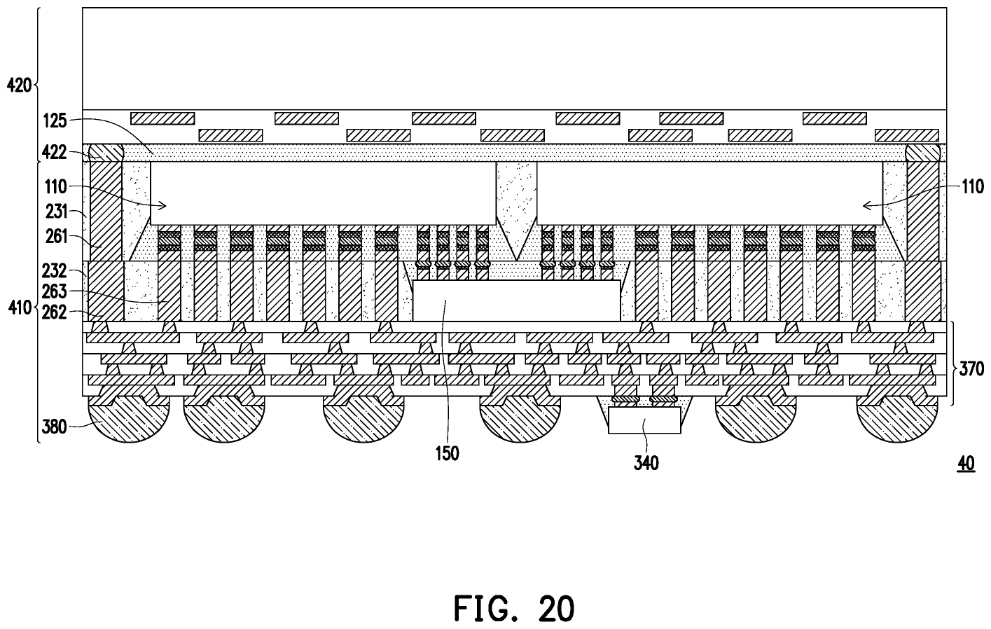

Referring to FIG. 20 and with reference to FIG. 19, an upper package component 420 may be disposed on the first insulating encapsulant 231, the first TIVs 261, and the first IC dies 110. For example, conductive terminals 422 of the upper package component 420 are physically and electrically coupled to the first TIVs 261. An underfill 125 is optionally formed in a gap between the upper package component 420 and the underlying structure to surround the conductive terminals 422. The upper package component 420 may include memory dies (not shown) and may be referred to as a memory package. In some embodiments, the aforementioned steps are performed in wafer form, and the resulting structure is cut by a singulation process (e.g., sawing, laser cutting, etching, a combination thereof, etc.), thereby separating the resulting structure into individual semiconductor packages 40. For example, the singulation process is performed to cut through the first insulating encapsulant 231, the second insulating encapsulant 232, and the redistribution structure 370. In some embodiments, the singulation process is performed when the electrical connectors 380 are attached to the tape 55, and after the singulation, the electrical connectors 380 are release from the tape 55.

In some embodiments, the structure underlying the upper package component 420 is collectively viewed as a lower package component 410 which may be referred to as an integrated fan-out (InFO) package. The semiconductor package 40 may be referred to as an InFO package-on-package (POP). It should be understood that the semiconductor package 40 illustrated in FIG. 20 is merely an example; the boning configuration of the first and second IC dies described herein may be adapted to apply to any suitable package type, such as a system-on-chip (SoC) package, a chip-on-wafer (CoW) package, a chip-on-wafer-on-substrate (CoWoS) package, or the like.

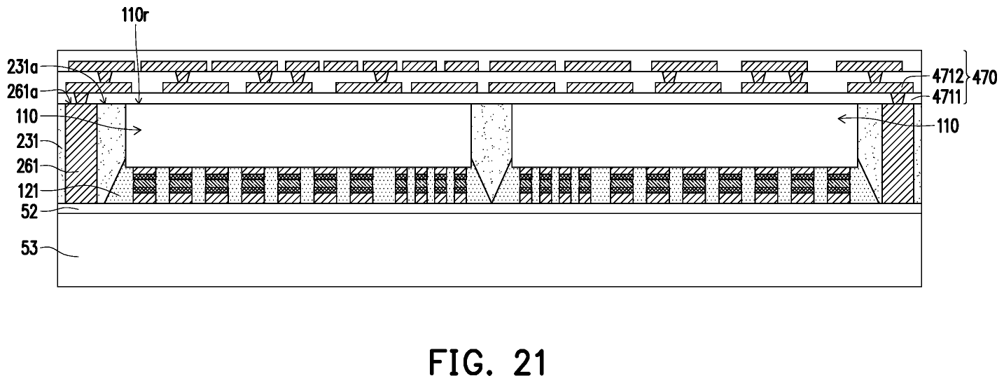

FIGS. 21 through 25 illustrate schematic cross-sectional views of intermediate steps during a process for forming a further semiconductor package, in accordance with some embodiments. Unless specified otherwise, like reference numerals in this embodiment represent like components in the embodiment shown in FIGS. 13 through 20 formed by like processes, and only differences will be the focus of the following discussion. Accordingly, the processes and applicable materials may not be repeated herein.

Referring to FIG. 21 and with reference to FIG. 14, after forming the first insulating encapsulant 231 as described in FIG. 14, a backside redistribution structure 470 may be formed on the first surface 231a of the first insulating encapsulant 231, the first surfaces 261a of the first TIVs 261, and the rear surface 110r of the first IC dies 110. The backside redistribution structure 470 may be similar to the redistribution structure 370 described in FIG. 12B. The backside redistribution structure 470 may include alternating stacked patterned dielectric layers 4711 and patterned conductive layers 4712. The backside redistribution structure 470 is shown as an example having three patterned dielectric layers 4711 and two patterned conductive layers 4712; however, more (or fewer) patterned dielectric layers and patterned conductive layers may be formed. The bottommost one of the patterned conductive layers 4712 may be physically and electrically coupled to the first surfaces 261a of the first TIVs 261. The topmost one of the patterned conductive layers 4712 may be fully covered by the topmost one of the patterned dielectric layers 4711 at this stage.

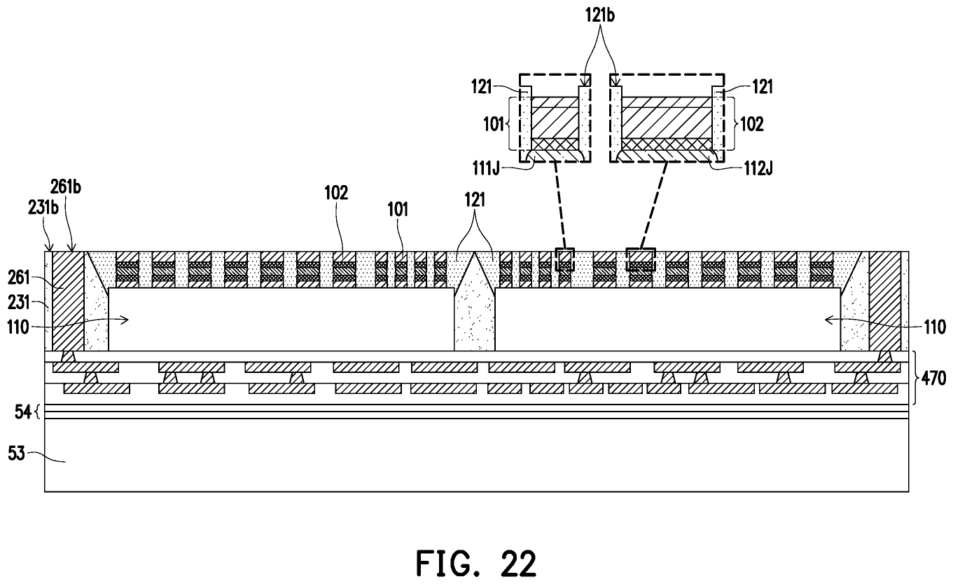

Referring to FIG. 22 and with reference to FIG. 21 and FIG. 15, the resulting structure illustrated in FIG. 21 may be flipped over, and the topmost one of the patterned dielectric layers 4711 of the backside redistribution structure 470 may be attached to the second temporary carrier 53 through, e.g., the second release layer 54. The first temporary carrier 51 may be removed by de-bonding the first release layer 52, thereby revealing the second surface 231b of the first insulating encapsulant 231, the second surfaces 261b of the first TIVs 261, and the surface 121b of the first underfill 121. The bonding of the second temporary carrier 53 and the de-bonding of the first temporary carrier 51 may be similar to the processes described in FIG. 3. In some embodiments, portions of the first and second conductive bumps 101′ and 102′ are removed to form the first and second conductive bumps 101 and 102 that are recessed from the surface 121b of the first underfill 121. The removing process may be similar to the process described in FIG. 3 or 15.

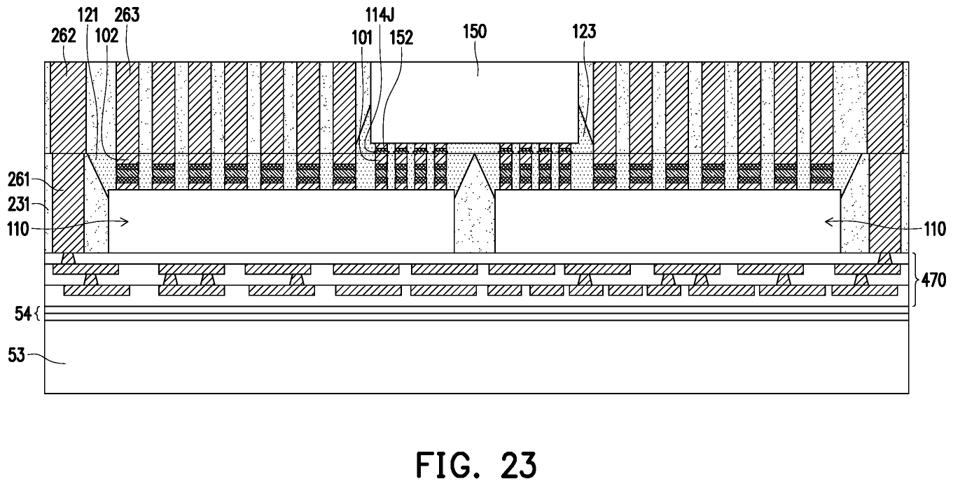

Referring to FIG. 23 and with reference to FIG. 22 and FIGS. 16-17, the second TIVs 262 may be formed on the first TIVs 261, and the third TIVs 263 may be formed on the second conductive bumps 102. The die connectors 152 of the second IC die 150 may be disposed on and electrically coupled to the first conductive bumps 101 through the fourth conductive joints 114J. The third underfill 123 is optionally formed to surround the die connectors 152 and the fourth conductive joints 114J. Subsequently, the second insulating encapsulant 232 may be formed on the first insulating encapsulant 231 to laterally cover each of the second and third conductive pillars 262 and 263, the second IC die 150, and the third underfill 123. The formation of the second and third TIVs 262 and 263, the coupling of the second IC die 150, and the formation of the second insulating encapsulant 232 may be similar to the processes described in FIGS. 16-17.

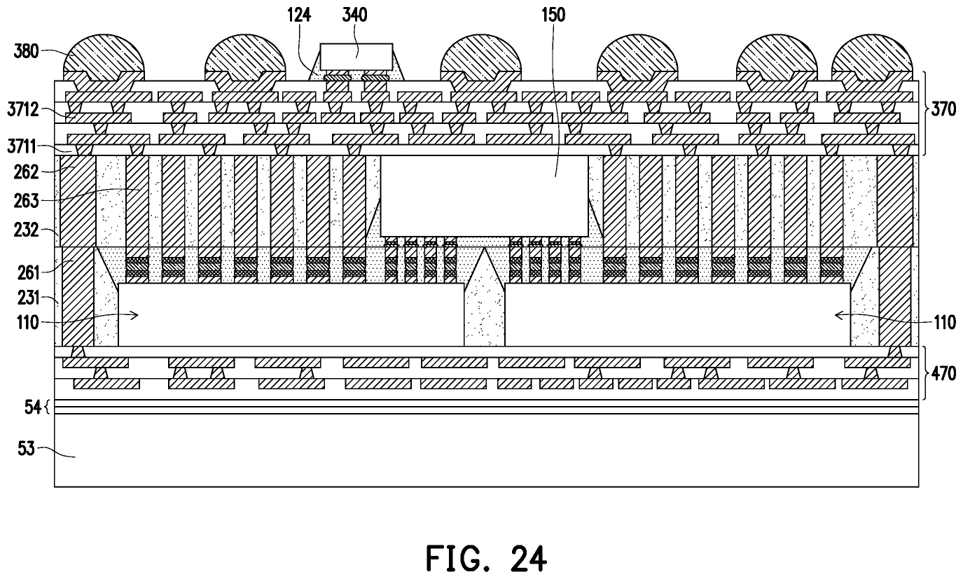

Referring to FIG. 24 and with reference to FIG. 23 and FIG. 18, the redistribution structure 370 including the patterned dielectric layers 3711 and the patterned conductive layers 3712 may be formed on the second insulating encapsulant 232, the second and third TIVs 262 and 263, and the second IC die 150. In some embodiments, the passive device 340 is attached to the redistribution structure 370. The fourth underfill 124 is optionally formed in a gap between the redistribution structure 370 and the passive device 340. In some embodiments, the electrical connectors 380 are formed on the topmost one of the patterned conductive layers 3712 and surround the passive device 340. The forming process of the redistribution structure 370, the attachment of the passive device 340, and the forming process of the electrical connectors 380 may be similar to the processes described in FIG. 18.

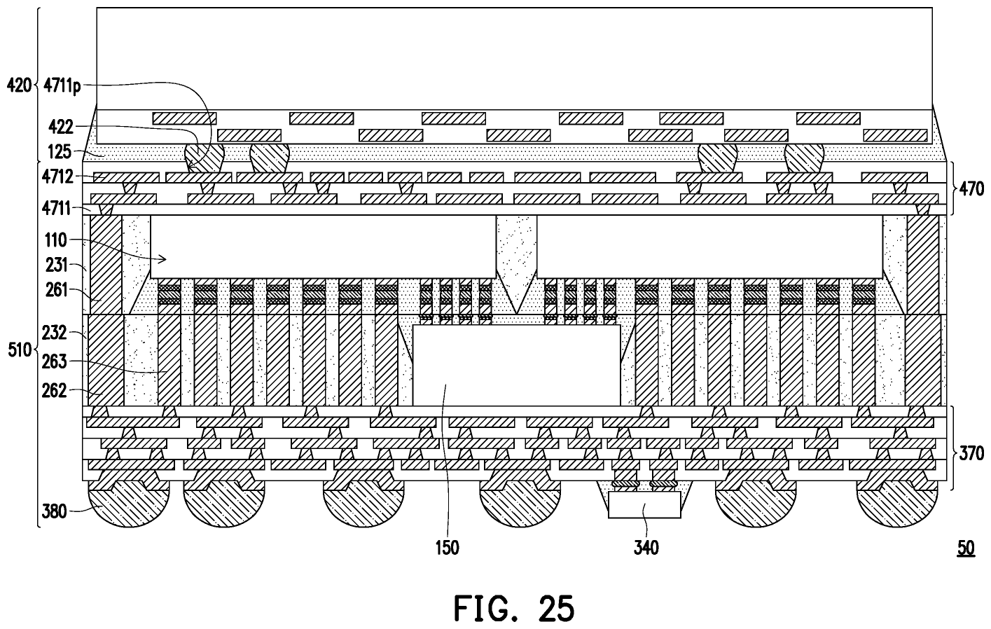

Referring to FIG. 25 and with reference to FIG. 24 and FIGS. 19-20, the second temporary carrier 53 may be removed by de-bonding the second release layer 54. Once the second temporary carrier 53 and the second release layer 54 are removed, the topmost one of the patterned dielectric layers 4711 of the backside redistribution structure 470 may be accessibly revealed. The resulting structure may be flipped over, and the electrical connectors 380 may be attached to the tape supported by the frame (e.g., as shown in FIG. 19). The topmost one of the patterned dielectric layers 4711 may be patterned to form openings 4711p. Subsequently, the upper package component 420 may be disposed on and electrically coupled to the backside redistribution structure 470. For example, the conductive terminals 422 of the upper package component 420 are inserted into the openings 4711p to be in physical and electrical contact with the topmost one of the patterned conductive layers 4712. The underfill 125 is optionally formed in a gap between the upper package component 420 and the backside redistribution structure 470 to surround the conductive terminals 422.

The aforementioned processes are similar to the processes described in FIGS. 19-20. In some embodiments, the aforementioned steps described in FIGS. 21-25 are performed in wafer form, and the resulting structure is cut by the singulation process, thereby separating the resulting structure into individual semiconductor packages 50. In some embodiments, the respective semiconductor package 50 includes the upper package component 420 stacked upon and electrically coupled to the lower package component 510. The semiconductor package 50 may be similar to the semiconductor package 40 described in FIG. 20, except that the lower package component 510 further includes the backside redistribution structure 470 connecting the upper package component 420 to the first TIVs 261.

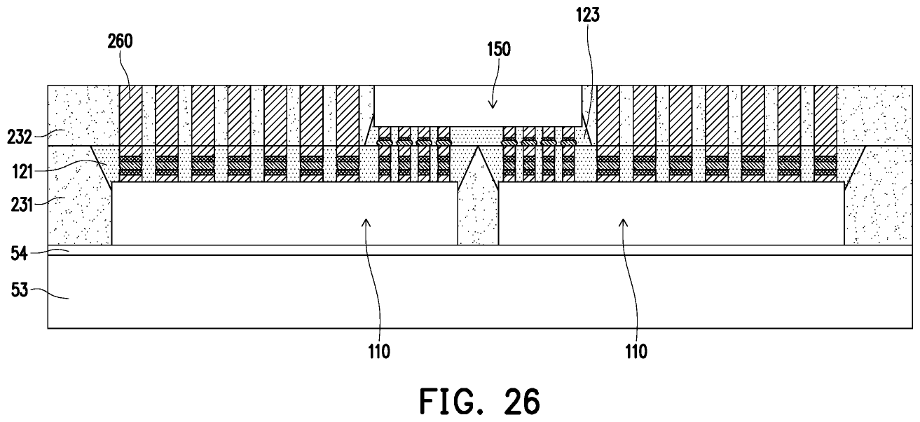

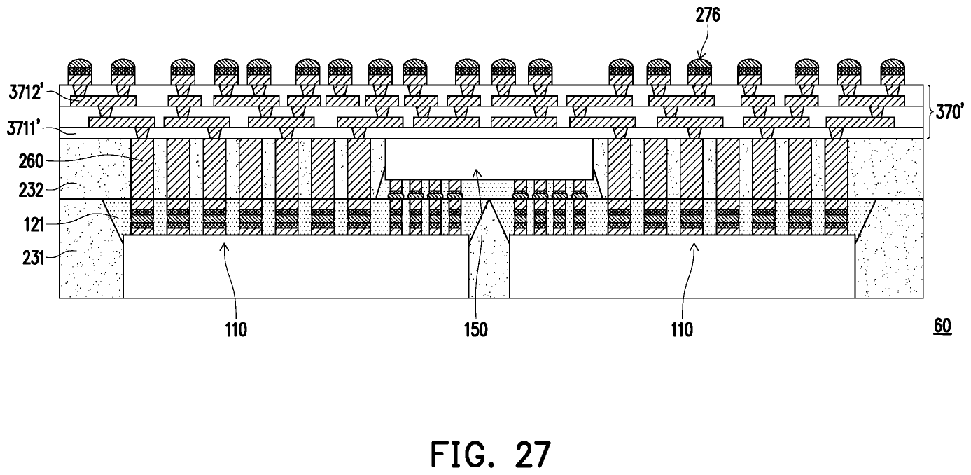

FIGS. 26 and 27 illustrate schematic cross-sectional views of intermediate steps during a process for forming a further semiconductor device, in accordance with some embodiments. Unless specified otherwise, like reference numerals in this embodiment represent like components in the embodiment shown in FIGS. 13-18 formed by like processes, and only differences will be the focus of the following discussion. Accordingly, the processes and applicable materials may not be repeated herein.

Referring to FIGS. 26-27 and with reference to FIGS. 17-18, the structure shown in FIG. 26 may be fabricated using the similar processes described in FIGS. 13-17, except that the first and second TIVs 261 and 262 are omitted in the structure in FIG. 26 and only TIVs 260 are formed. A redistribution structure 370′ may be formed on the second insulating encapsulant 232, the TIVs 260, and the second IC die 150. The redistribution structure 370′ including the patterned dielectric layers 3711′ and the patterned conductive layers 3712′ may be similar to the redistribution structure 370 described in FIG. 18. The redistribution structure 370′ is shown as an example having three patterned dielectric layers 3711′ and three patterned conductive layers 3712′; however, more or fewer patterned dielectric layers and patterned conductive layers may be formed in the redistribution structure 370′. In some embodiments, the electrical connectors 276 are formed on the topmost one of the patterned conductive layers 3712′ of the redistribution structure 370′ to be electrical coupled to the TIVs 260. The electrical connectors 276 may be similar to the electrical connectors 276 described in FIG. 11A.

In some embodiments, after forming the electrical connectors 276, the second temporary carrier 53 is removed through de-bonding the second release layer 54. The aforementioned processes are similar to the processes described in FIGS. 19-20. In some embodiments, the aforementioned steps are performed in wafer form, and the resulting structure is cut by the singulation process, thereby separating the resulting structure into individual semiconductor packages 60.

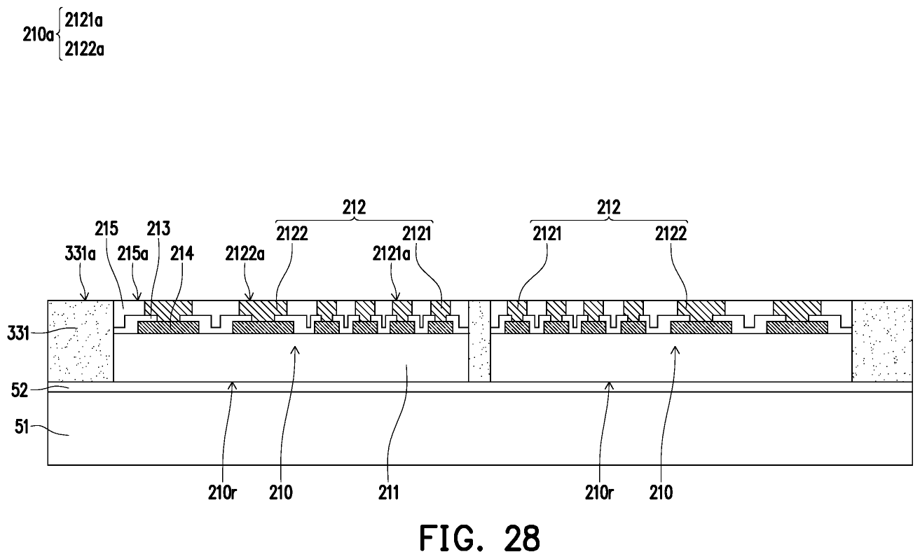

FIGS. 28 through 31 illustrate schematic cross-sectional views of intermediate steps during a process for forming a further semiconductor device, in accordance with some embodiments. Like reference numerals in this embodiment represent like components in the previous embodiments.

Referring to FIG. 28, first IC dies 210 may be disposed over the first temporary carrier 51 through, e.g., a pick-and-place process. In some embodiments, rear surfaces 210r of the first IC dies 210 are attached to the first temporary carrier 51 through the first release layer 52 (e.g., a die attach film). The first IC dies 210 may be similar to the first IC dies 110 described in FIG. 1. For example, the respective first IC die 210 includes a semiconductor substrate 211 which may be similar to the semiconductor substrate 111. The respective first IC die 210 may include a passivation layer 213 disposed on the semiconductor substrate 211 and conductive pads 213 disposed on the semiconductor substrate 211 and partially covered by the passivation layer 213. The conductive pads 213 may be aluminum pads and the die connectors 212 may land on the conductive pads 213 with a one-to-one correspondence. The die connectors 212, similar to the die connectors 112, may include first connectors 2121 and second connectors 2122. The respective first IC die 210 may include a protective layer 215 formed on the passivation layer 213 and laterally covering each of the die connectors 212.

In some embodiments, after the placement of the first IC dies 210, a first insulating encapsulant 331 is formed over the first temporary carrier 51 to laterally cover the respective first IC die 210. The material and the forming process of the first insulating encapsulant 331 may be similar to the first insulating encapsulant 131 described in FIG. 2. For example, a first surface 331a of the first insulating encapsulant 331 and an active surface 210a of the respective first IC die 210 are planarized to be substantially leveled (or coplanar), within process variations. The active surface 210a of the respective first IC die 210 may include surfaces 2121a of the first connectors 2121 and surfaces 2122a of the second connectors 2122a. In some embodiments, a surface 215a of the protective layer 215 is substantially leveled (or coplanar) with the surfaces 2121a and 2122a of the first and second connectors 2121 and 2122.

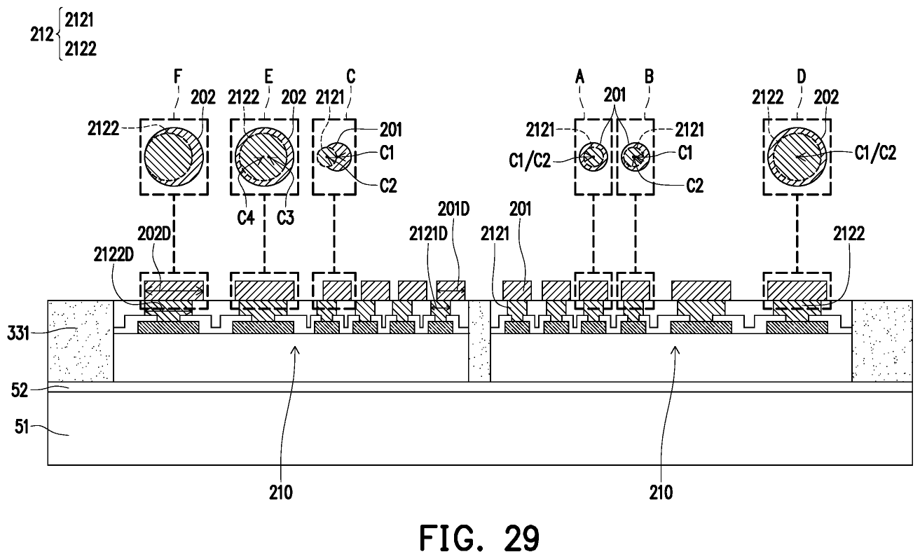

Referring to FIG. 29 and with reference to FIG. 28, first conductive bumps 201 may be formed on the first connectors 2121 with a one-to-one correspondence, and second conductive bumps 202 may be formed on the second connectors 2122 with a one-to-one correspondence. In some embodiments, the first and second conductive bumps 201 and 202 are formed by initially forming a first sublayer (e.g., a titanium sublayer) of a seed material on the active surfaces 210a of the first IC dies 210 and the first insulating encapsulant 331, forming a second sublayer (e.g., a copper layer) of the seed material on the first sublayer, forming a patterned photoresist on the second sublayer, plating a metallic layer (e.g., a copper layer) in the openings of the patterned photoresist, removing the patterned photoresist, and removing excess portions of the seed material on which the metallic layer is not formed. The remaining portions form the first and second conductive bumps 201. The first and second conductive bumps 202 may be referred to as first and second conductive pads. In some embodiments, an interface between the respective first conductive bump 201 and the underlying first connector 2121 and an interface between the respective second conductive bump 202 and the underlying second connector 2122 are free of solder material. In some embodiments, a lateral dimension (e.g., a width of a diameter) 201D of the first conductive bump 201 is greater than (or substantially equal to) a lateral dimension 2121D of the underlying first connector 2121. A lateral dimension (e.g., a width of a diameter) 202D of the second conductive bump 202 may be greater than (or substantially equal to) a lateral dimension 2122D of the underlying second connector 2121.

As mentioned in the preceding paragraphs, the formation of the first insulating encapsulant may cause the shift of the first IC dies. The first and/or second conductive bumps 201/202 may be formed with offset to compensate for the expected shift. The structures in the dashed boxes in FIG. 29 illustrate various top-down views of the first and second conductive bumps 201 and 202 and the underlying die connectors 212 as examples. For example, as shown in the dashed box A, a center C1 of the first conductive bump 201 is substantially aligned with a center C2 of the underlying first connector 2121 in the stacking direction of the first conductive bump 201 and the first connector 2121. In some embodiments, as shown in the dashed box B, the center C1 of the first conductive bump 201 is offset from the center C2 of the underlying first connector 2121 by a non-zero distance, and the first conductive bump 201 and the first connector 2121 fully overlap in the stacking direction of the first conductive bump 201 and the first connector 2121. In some embodiments, as shown in the dashed box C, the first conductive bump 201 partially overlaps the first connector 2121 in the stacking direction of the first conductive bump 201 and the first connector 2121, and a portion of the first connector 2121 is accessibly exposed by the first conductive bump 201.

In some embodiments, as shown in the dashed box D, a center C3 of the second conductive bump 202 is substantially aligned with a center C4 of the underlying second connector 2122 in the stacking direction of the second conductive bump 202 and the second connector 2122. In some embodiments, as shown in the dashed box E, the center C3 of the second conductive bump 202 is offset from the center C4 of the underlying second connector 2122 by a non-zero distance, and the second conductive bump 202 and the second connector 2122 fully overlap in the stacking direction of the second conductive bump 202 and the second connector 2122. In some embodiments, as shown in the top-down view of the dashed box F, the edge of the second conductive bump 202 may partially coincide the edge of the second connector 2122. Although the first and second conductive bumps 201 and 202 and the first and second connectors 2121 and 2122 are illustrated as a circular shape in the top-down view, it should be understood that the first and second conductive bumps 201 and 202 and the first and second connectors 2121 and 2122 can have any shape, such as a rectangular shape, a square shape, an oval shape, a polygonal shape, etc.

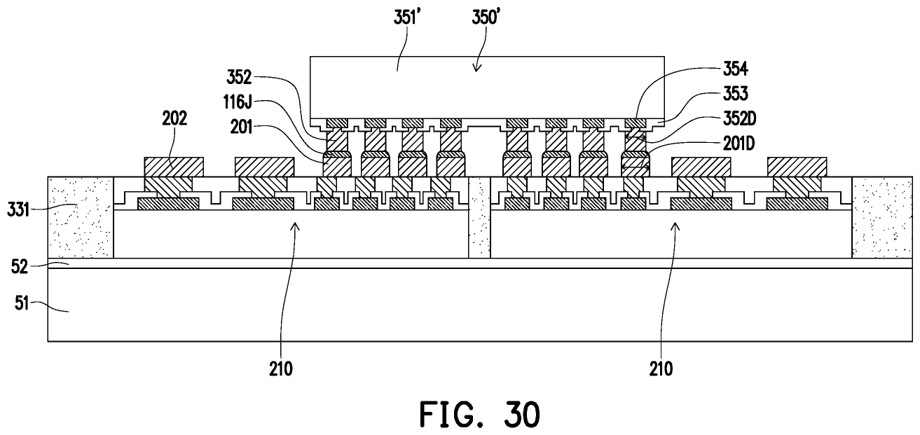

Referring to FIG. 30 and with reference to FIG. 29, at least one second IC die 350′ may be attached to the first conductive bumps 201, where the second IC die 350′ may be similar to the second IC die 150′ described in FIG. 5. For example, the second IC die 350′ includes a semiconductor substrate 351′ which is similar to the semiconductor substrate 151′. The second IC die 350 may include a passivation layer 353 disposed on the semiconductor substrate 351′ and a plurality of conductive pads 354 disposed on the semiconductor substrate 351′ and partially covered by the passivation layer 353. The conductive pads 354 may be aluminum pads and the die connectors 352 may land on the conductive pads 354 with a one-to-one correspondence. The die connectors 352, similar to the die connectors 152, may be coupled to the first conductive bumps 201 through conductive joints 116J (e.g., solder joints). In some embodiments, a lateral dimension (e.g., a width of a diameter) 352D of the respective die connector 352 is greater than (or substantially equal to) the lateral dimension 201D of the underlying first conductive bumps 201. In some embodiments, the respective conductive joint 116J may have a surface area coupled to the die connector 352 less than a surface area coupled to the first conductive bumps 201.

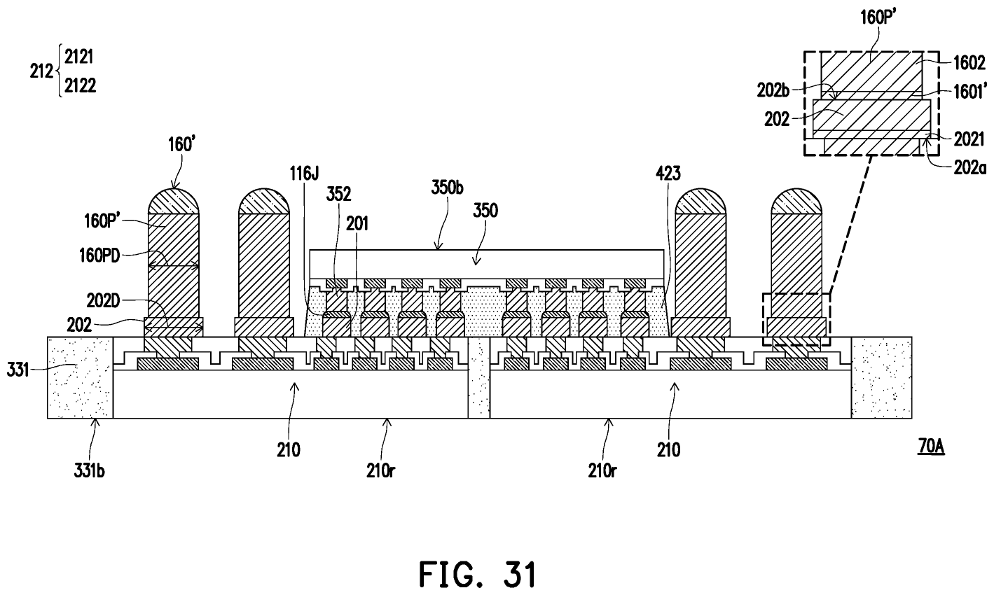

Referring to FIG. 31 and with reference to FIG. 30, an underfill 423 may be formed in a gap between the first IC dies 210 and the second IC die 350 to surround the first conductive bumps 201, the conductive joints 116J, and the die connectors 352. The underfill 423 may be similar to the third underfill 123 described in FIG. 6. In some embodiments, the underfill 423 is in physical contact with the portion of the die connectors 212 of the first IC dies 210 which is exposed by the overlying first or second conductive bumps 201 or 202. In some embodiments, a thinning process is performed on the second IC die 350′ to reduce the overall thickness so as to form the second IC die 350 having a thinned rear surface 350b. The thinning process may be similar to the process described in FIG. 6. Alternatively, the thinning process is skipped.

In some embodiments, electrical connectors 160′ may be formed on the second conductive bumps 202. The electrical connectors 160′ may be similar to the electrical connectors 160 described in FIG. 7. For example, the pillar portion 160P′ of the respective electrical connector 160′ lands on the second conductive bump 202. A lateral dimension (e.g., a width of a diameter) 160PD of the pillar portion 160P′ may be less than the lateral dimension 202D of the underlying second conductive bump 202. The pillar portion 160P′ may include a seed layer 1601′ overlying the surface 202b of the second conductive bump 202 and a metallic layer 1602 overlying the seed layer 1601′. In some embodiments, the second conductive bump 202 includes a seed layer 2021 at the surface 202a opposite to the surface 202b, where the surfaces 202a and 202b are substantially flat.

With continued reference to FIG. 31 and FIG. 30, the first temporary carrier 51 may be removed by de-bonding the first release layer 52. The de-bonding of the first temporary carrier 51 may be similar to the process described in FIG. 3. After removing the first temporary carrier 51 and the first release layer 52, a second surface 331b of the first insulating encapsulant 331 and the rear surfaces 210r of the first IC dies 210 may be accessibly revealed and may be substantially leveled (or coplanar). A singulation process is optionally performed to dice the resulting structure into individual semiconductor devices 70A.

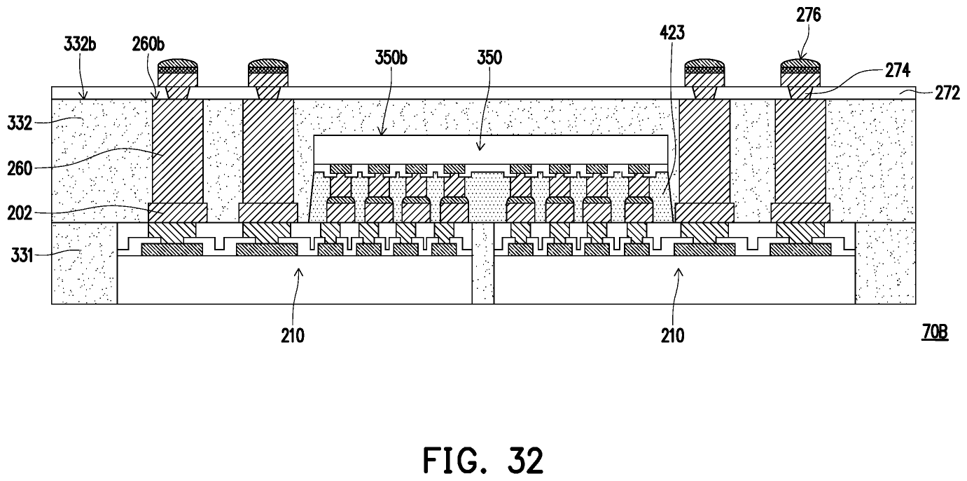

FIG. 32 illustrates a schematic cross-sectional view of a further semiconductor device, in accordance with some embodiments. Like reference numerals in this embodiment represent like components in the previous embodiments. Referring to FIG. 32 and with reference to FIG. 31 and FIG. 11A, a semiconductor devices 70B is similar to the semiconductor device 70A described in FIG. 31, except that the semiconductor devices 70B further includes a second insulating encapsulant 332 formed on the first insulating encapsulant 331 to cover the second conductive bumps 202, the TIVs 260, the second IC die 350, and the underfill 423. The second insulating encapsulant 332 may be similar to the second insulating encapsulant 132 described in FIG. 11A. In some embodiments, the surfaces 260b of the TIVs 260 are substantially leveled (or coplanar) with the surface 332b of the second insulating encapsulant 332, within process variations. The thinned rear surface 350b of the second IC die 350 may be fully covered by the second insulating encapsulant 332. Alternatively, the thinned rear surface 350b of the second IC die 350 may be substantially leveled (or coplanar) with the surface 332b of the second insulating encapsulant 332, within process variations.

In some embodiments, the semiconductor devices 70B includes the dielectric layer 272 formed on the surfaces 260b of the TIVs 260 and the surface 332b of the second insulating encapsulant 332. The conductive pattern 274 may be formed through the dielectric layer 272 to be in physical and electrical contact with the surfaces 260b of the TIVs 260. In some embodiments, the semiconductor devices 70B includes the electrical connectors 276 formed on the conductive pattern 274 to be electrical coupled to the TIVs 260. The dielectric layer 272, the conductive pattern 274, and the electrical connectors 276 may be similar to the dielectric layer 272, the conductive pattern 274, and the electrical connectors 276 described in FIG. 11A.

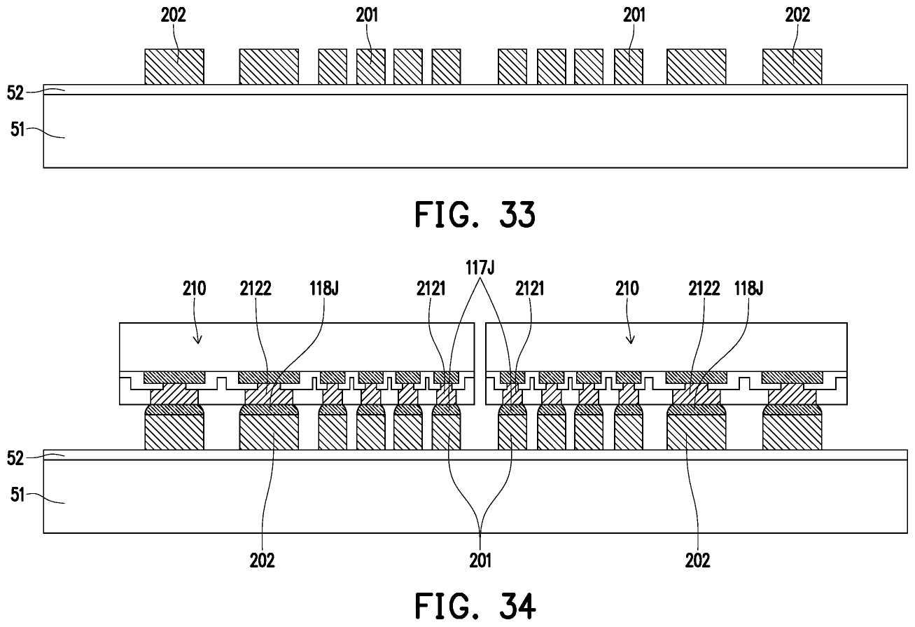

FIGS. 33 through 37 illustrate schematic cross-sectional views of intermediate steps during a process for forming a semiconductor device, in accordance with some embodiments. Unless specified otherwise, like reference numerals in this embodiment represent like components in the embodiment shown in FIGS. 28-31 formed by like processes, and only differences will be the focus of the following discussion. Accordingly, the processes and applicable materials may not be repeated herein.

Referring to FIG. 33, the first conductive bumps 201 and the second conductive bumps 202 may be formed over the first temporary carrier 51. As mentioned in the previous embodiments, to achieve the fine-pitched configuration, the shift of the subsequently-attached first IC dies due to the subsequently-formed first insulating encapsulant may be taken into consideration when forming the first and second conductive bumps 201 and 202. For example, the calibrated data of the shift may be produced using simulation and/or experimental methods, and the first and second conductive bumps 201 and 202 are formed with offset to compensate for the expected shift based on the calibrated data.

Referring to FIG. 34 and with reference to FIG. 33, the first IC dies 210 may be coupled to the first and second conductive bumps 201 and 202. For example, the first connectors 2121 of the respective first IC die 210 are bonded to the first conductive bumps 201 through the first conductive joints 117J, and the second connectors 2122 of the respective first IC die 210 are bonded to the second conductive bumps 202 through the second conductive joints 118J, where the first and second conductive joints 117J may be solder joints.

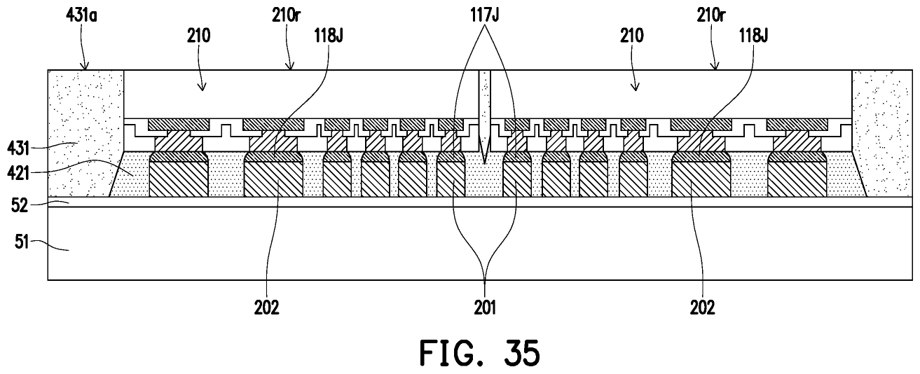

Referring to FIG. 35 and with reference to FIG. 34, the first underfill 421 may be formed over the first temporary carrier 51 to cover the first and second conductive bumps 201 and 202 and the first and second conductive joints 117J and 118J. Next, a first insulating encapsulant 431 may be formed over the first temporary carrier 51 to laterally cover the first IC dies 120 and the first underfill 421. The first underfill 421 and the first insulating encapsulant 431 may be similar to the first underfill 121 and the first insulating encapsulant 131 described in FIG. 2. In some embodiments, a first surface 431a of the first insulating encapsulant 431 and the rear surfaces 210r of the first IC dies 210 are planarized and substantially leveled (or coplanar), within process variations.

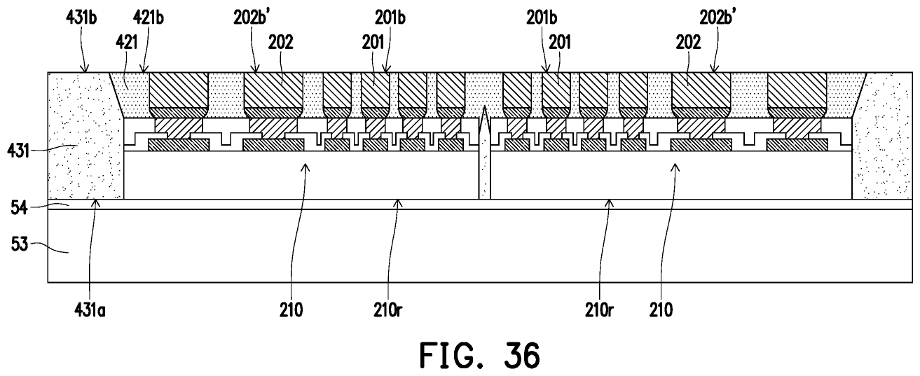

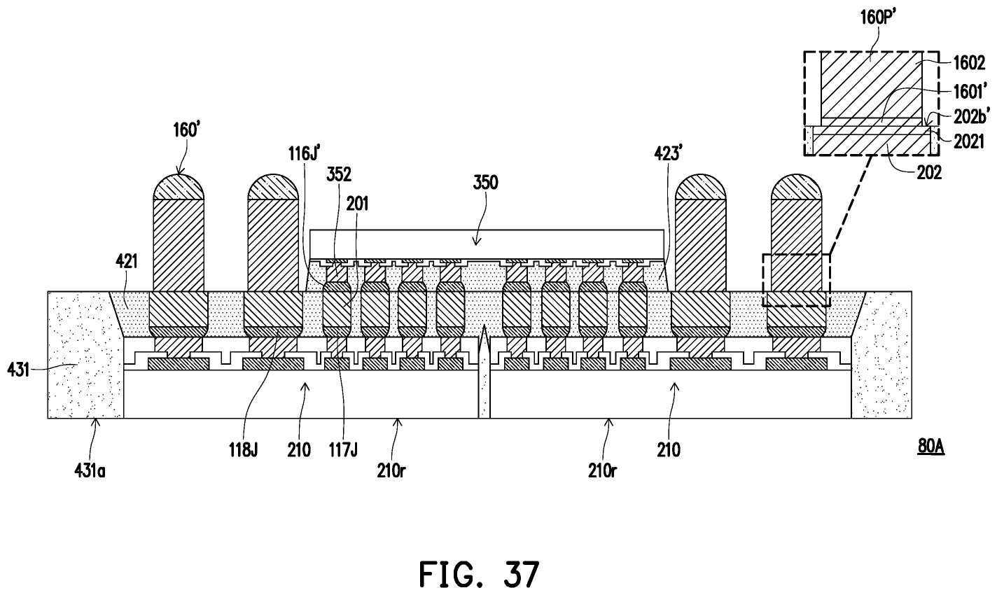

Referring to FIG. 36 and with reference to FIG. 35, the resulting structure of FIG. 35 may be flipped over to be attached to the second temporary carrier 53. For example, the first surface 431a of the first insulating encapsulant 431 and the rear surfaces 210r of the first IC dies 210 are attached to the second temporary carrier 53 through the second release layer 54. The first temporary carrier 51 may be removed through de-bonding the first release layer 52 to accessibly reveal a second surface 431b of the first insulating encapsulant 431, a surface 421b of the first underfill 421, surfaces 201b and 202b′ of the first and second conductive bumps 201 and 202. The bonding process of the second temporary carrier 53 and the de-bonding process of the first temporary carrier 51 may be similar to the processes described in FIG. 3. The seed layer (not individually shown) of the respective first and second conductive bumps 201 and 202 may remain or may be partially removed as described in FIG. 3.

Referring to FIG. 37 and with reference to FIG. 36 and with reference to FIGS. 30-31, the die connectors 352 of the second IC die 350 may be attached to the surfaces 201b of the first conductive bumps 201 through the third conductive joints 116J′. The second underfill 423′ is optionally formed on the first underfill 421 to surround the die connectors 352 of the second IC die 350 and the third conductive joints 116J′ for protection. The electrical connectors 160′ may be formed on the second conductive bumps 202 to surround the second IC die 350. Subsequently, the second temporary carrier 53 may be removed through de-bonding the second release layer 54 to accessibly reveal the first surface 431a of the first insulating encapsulant 431 and the rear surfaces 210r of the first IC dies 210. The attachment of the second IC die 350, the formation of the second underfill 423′, the formation of the electrical connectors 160′, and the de-bonding of the second temporary carrier 53 may be similar to the processes described in FIGS. 30-31.

A semiconductor device 80A shown in FIG. 37 is similar to the semiconductor devices 70A shown in FIG. 31, and the difference therebetween includes that two of opposing ends of the respective first conductive bumps 201 of the semiconductor device 80A may have conductive joints (e.g., 117J and 116J′) formed thereon, and one end of the respective second conductive bumps 202 of the semiconductor device 80A facing the first IC die 210 may have the second conductive joints 118J formed thereon. The semiconductor device 80A may have the first underfill 421 encapsulated in the first insulating encapsulant 431 and laterally covering the first and second conductive joints 117J and 118J and the first and second conductive bumps 201 and 202. The pillar portion 160P′ may include a seed layer 1601′ formed on the surface 202b′ of the second conductive bump 202 and the metallic layer 1602 formed on the seed layer 1601′. In some embodiments, the second conductive bump 202 includes the seed layer 2021 at the surface 202b′, and the seed layer 1601′ of the pillar portion 160P′ are in direct contact with the seed layer 2021 of the second conductive bump 202.

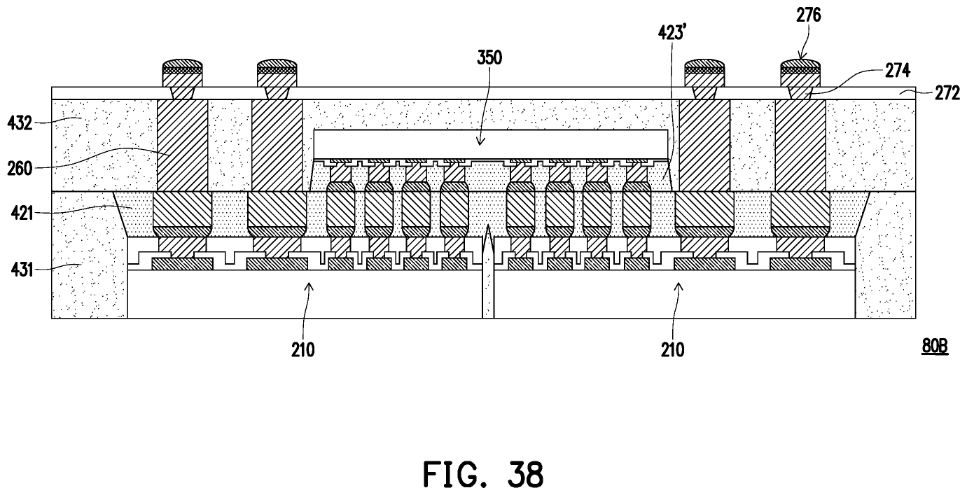

FIG. 38 illustrates a schematic cross-sectional view of a semiconductor device, in accordance with some embodiments. Like reference numerals in this embodiment represent like components in the previous embodiments. Referring to FIG. 38 and with reference to FIG. 37 and FIG. 32, a semiconductor device 80B is similar to the semiconductor device 80A, except that the semiconductor devices 80B further includes the second insulating encapsulant 432 formed on the first insulating encapsulant 431 to cover the TIVs 260, the second IC die 350, and the second underfill 423′. The semiconductor device 80B may include the dielectric layer 272 formed on the TIVs 260 and the second insulating encapsulant 432, the conductive pattern 274 formed through the dielectric layer 272 to be in physical and electrical contact with the TIVs 260, and the electrical connectors 276 formed on the conductive pattern 274 to be electrical coupled to the TIVs 260. The second insulating encapsulant 432, the dielectric layer 272, the conductive pattern 274, and the electrical connectors 276 may be similar to the second insulating encapsulant 332, the dielectric layer 272, the conductive pattern 274, and the electrical connectors 276 described in FIG. 32.

According to some embodiments, a device includes first IC dies disposed side-by-side, a second IC die overlapping and electrically coupled to the first IC dies, and first conductive features. Each of the first IC dies includes first die connectors and second die connectors, where a first pitch of the first die connectors is less than a second pitch of the second die connectors. The second IC die includes third die connectors, where a third pitch of the third die connectors is substantially equal to the first pitch of the first die connectors. The first conductive features are interposed between and electrically coupled to the first die connectors and the third die connectors. Each of the first conductive features includes at least a first conductive bump and at least a first conductive joint.

According to some alternative embodiments, a device includes first IC dies disposed side-by-side, a second IC die stacked upon and electrically coupled to the first IC dies, conductive pillars disposed over the first IC dies, a first electrical connection electrically connected to the second IC die and one of the first IC dies, and a second electrical connection electrically connected to one of the conductive pillars and the one of the first IC dies. The first electrical connection includes a first solder joint physically connected to a die connector of the second IC die. An interface between the second electrical connection and the one of the conductive pillars is free of solder material, where a dimension of a first conductive bump of the first electrical connection is less than that of a second conductive bump of the second electrical connection.

According to some alternative embodiments, a method includes coupling first IC dies to a first side of first conductive features and a first side of second conductive features, wherein a pitch of the first conductive features is less than that of the second conductive features; coupling a second IC die to a second side of the first conductive features opposite to the first side of the first conductive features, wherein solder joints are formed on the second side of the first conductive features; and forming conductive pillars on a second side of the second conductive features opposite to the first side of the second conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
first integrated circuit (IC) dies disposed side-by-side, each of the first IC dies comprising first die connectors and second die connectors, wherein a first pitch of the first die connectors is less than a second pitch of the second die connectors;
a second IC die overlapping and electrically coupled to the first IC dies, the second IC die comprising third die connectors, wherein a third pitch of the third die connectors is substantially equal to the first pitch of the first die connectors; and
first conductive features interposed between and electrically coupled to the first die connectors and the third die connectors, each of the first conductive features comprising at least a first conductive bump and at least a first conductive joint.

2. The device of claim 1, wherein the first conductive joint comprises:
a first portion having a curved sidewall and physically connected to a corresponding third die connector; and
a second portion connected to the first portion and the conductive bump, the second portion having a substantially vertical sidewall connected to the curved sidewall of the first portion.

3. The device of claim 1, wherein each of the first conductive features further comprises:
a second conductive joint physically coupled to the first conductive bump and a corresponding first die connector, and the second conductive joint comprising a curved sidewall.

4. The device of claim 1, wherein a lateral dimension of the first conductive bump is greater than a lateral dimension of a corresponding first die connector and is also greater than a lateral dimension of a corresponding third die connector.

5. The device of claim 1, wherein the first conductive bump is laterally offset from a corresponding first die connector.

6. The device of claim 1, wherein an interface between the first conductive bump and the first die connector is free of solder material.

7. The device of claim 1, further comprising:
second conductive features surrounding the first conductive features, each of the second conductive features comprising:
a second conductive bump comprising a first side facing a corresponding second die connector and a second side opposite to the first side;
conductive pillars surrounding the second IC die, each of the conductive pillars being in direct contact with the second side of one of the second conductive bump.

8. The device of claim 7, wherein a lateral dimension of the conductive pillars is less than a lateral dimension of a corresponding one of the second conductive bumps.

9. The device of claim 7, wherein each of the conductive pillars comprises:
a first portion physically connected to the second side of the one of the second conductive bump and comprising a lateral dimension substantially equal to that of the second side of the one of the second conductive bump; and
a second portion connected to the first portion and comprising a lateral dimension greater than the lateral dimension of the first portion.

10. The device of claim 7, wherein each of the second conductive features further comprises:
a second conductive joint connected to the first side of the second conductive bump and the corresponding second die connector, the second conductive joint comprising a curved sidewall.

11. The device of claim 1, further comprising:
a first underfill surrounding the first and second die connectors and the first conductive features, wherein the first conductive joint of each of the first conductive features comprises a first portion protruded from the first underfill and a second portion connected to the first portion and inserted into the first underfill.

12. The device of claim 11, further comprising:
a second underfill disposed on the first underfill and surrounding the first portion of the first conductive joint of each of the first conductive features and the third die connectors of the second IC die; and
conductive pillars surrounding the second IC die and coupled to the second die connectors of the first IC dies, wherein a portion of the second underfill extends between adjacent two of the conductive pillars that are in proximity of the second IC die.

13. A device, comprising:
first IC dies disposed side-by-side;
a second IC die stacked upon and electrically coupled to the first IC dies;
conductive pillars disposed over the first IC dies;
a first electrical connection electrically connected to the second IC die and one of the first IC dies, the first electrical connection comprising a first solder joint physically connected to a die connector of the second IC die; and
a second electrical connection electrically connected to one of the conductive pillars and the one of the first IC dies, an interface between the second electrical connection and the one of the conductive pillars being free of solder material, wherein a dimension of a first conductive bump of the first electrical connection is less than that of a second conductive bump of the second electrical connection.

14. The device of claim 13, wherein the first electrical connection further comprises:
a second solder joint physically connected to a die connector of the one of the first IC dies.

15. The device of claim 13, wherein an interface between the first electrical connection and a die connector of the one of the first IC dies is free of solder material.

16. The device of claim 13, wherein the first solder joint comprises a curved sidewall connected to the die connector of the second IC die and a substantially vertical sidewall connected to the curved sidewall.

17. A method, comprising:
coupling first IC dies to a first side of first conductive features and a first side of second conductive features, wherein a pitch of the first conductive features is less than that of the second conductive features;
coupling a second IC die to a second side of the first conductive features opposite to the first side of the first conductive features, wherein solder joints are formed on the second side of the first conductive features; and
forming conductive pillars on a second side of the second conductive features opposite to the first side of the second conductive features.

18. The method of claim 17, further comprising:
forming an underfill to surround the first IC dies, the first conductive features, and the second conductive features before coupling the second IC die to the second side of the first conductive features;
recessing the first conductive features from the underfill; and
forming the solder joints on the second side of the first conductive features, wherein each of the solder joints comprises a first portion inserted into the underfill and a second portion connected to the first portion and protruded from the underfill.

19. The method of claim 18, wherein:
recessing the second conductive features from the underfill when recessing the first conductive features from the underfill; and
forming the conductive pillars on second side of the second conductive features, wherein each of the conductive pillars comprises a first portion inserted into the underfill and a second portion connected to the first portion and protruded from the underfill.

20. The method of claim 17, wherein coupling the first IC dies to the first side of the first conductive features and the first side of the second conductive features comprises:
forming the first conductive features and the second conductive features respectively on first and second die connectors of the first IC dies, wherein a lateral dimension of each of the first conductive features is greater than that of a corresponding one of the first die connectors, and a lateral dimension of each of the second conductive features is greater than that of a corresponding one of the second die connectors.
